(19) United States
(12) Patent Application Publication
(10) Pub. No.: US 2025/0192050 A1
(43) Pub. Date: Jun. 12, 2025

(54) SEMICONDUCTOR MEMORY DEVICE

(71) Applicant: SAMSUNG ELECTRONICS CO., LTD., Suwon-si (KR)

(72) Inventors: Jinwoo Han, Suwon-si, Gyeonggi-do (KR); Jeon Il Lee, Suwon-si, Gyeonggi-do (KR)

(21) Appl. No.: 18/770,371

(22) Filed: Jul. 11, 2024

(30) Foreign Application Priority Data
Dec. 12, 2023 (KR) 10-2023-0179927

(51) Int. Cl. H01L 23/528; H01L 23/522; H10B 12/00

(52) U.S. Cl. CPC H01L 23/5286; H01L 23/5226; H01L 23/5283; H10B 12/315; H10B 12/482; H10B 12/488

(57) ABSTRACT

An example semiconductor memory device includes a first substrate, a first interlayer insulating layer covering the first substrate, a second substrate disposed on the first interlayer insulating layer, a second interlayer insulating layer covering an active surface of the second substrate, a third interlayer insulating layer covering an inactive surface of the second substrate, a power delivery network pattern disposed in the third interlayer insulating layer, an inner penetration via, a first outer penetration via, and a second outer penetration via. The inner penetration via extends through the second substrate and connects transistors with the power delivery network pattern. The first outer penetration via extends through at least one of the second interlayer insulating layer, the second substrate, and the third interlayer insulating layer. The second outer penetration via extends through the second interlayer insulating layer, the second substrate, and the third interlayer insulating layer.

### CROSS-REFERENCE TO RELATED APPLICATION

This application claims priority under 35 U.S.C. § 119 to Korean Patent Application No. 10-2023-0179927, filed on Dec. 12, 2023, in the Korean Intellectual Property Office, the entire contents of which are hereby incorporated by reference.

### BACKGROUND

A semiconductor memory device includes a plurality of circuit regions. For example, the semiconductor memory device has a cell array region for memory elements and a peripheral region, in which circuits for driving the memory elements and performing data input/output operations are provided. Various devices are disposed in each region, and here, the electrical characteristics required for the devices may vary from region to region. Meanwhile, as the integration density of the semiconductor memory device increases, it is necessary to form more circuits within a limited chip area. Thus, it is necessary to reduce a form factor of the semiconductor memory device while optimizing the devices in each region in order to improve the reliability of the semiconductor memory device.

### SUMMARY

The present disclosure relates to a semiconductor memory device of a small size, and a semiconductor memory device with improved electrical characteristics.

In some implementations, a semiconductor memory device may include a first substrate having a cell array region, a first interlayer insulating layer covering the first substrate, a second substrate disposed on the first interlayer insulating layer, the second substrate having a core region, a second interlayer insulating layer covering an active surface of the second substrate, a third interlayer insulating layer covering an inactive surface of the second substrate, a power delivery network pattern disposed in the third interlayer insulating layer, an inner penetration via provided to penetrate the second substrate and connect transistors, which are formed on the active surface of the second substrate, to the power delivery network pattern, a first outer penetration via provided to penetrate at least some of the second interlayer insulating layer, the second substrate, and the third interlayer insulating layer and coupled to the power delivery network pattern, and a second outer penetration via provided to penetrate the second interlayer insulating layer, the second substrate, and the third interlayer insulating layer and electrically connected to the cell array region.

In some implementations, a semiconductor memory device may include a first substrate having a cell array region, a first interlayer insulating layer covering the first substrate, first interconnection lines disposed in the first interlayer insulating layer and electrically connected to the cell array region, a second substrate disposed on the first interlayer insulating layer, the second substrate having a logic region electrically connected to the cell array region, a transistor provided in the logic region and on a first surface of the second substrate, a second interlayer insulating layer covering the first surface of the second substrate, second interconnection lines provided in the second interlayer insulating layer and electrically connected to the transistor, a third interlayer insulating layer covering a second surface, which are opposite to the first surface of the second substrate, a power delivery network pattern provided in the third interlayer insulating layer, a first outer penetration via provided to penetrate at least some of the second interlayer insulating layer, the second substrate, and the third interlayer insulating layer and connected to the power delivery network pattern, and a second outer penetration via provided to penetrate the second interlayer insulating layer, the second substrate, and the third interlayer insulating layer and connected to the first interconnection lines. The power delivery network pattern may include a first head portion and a first via portion, which is extended from a top surface of the first head portion toward the second substrate. The first interconnection lines may include a second head portion and a second via portion, which is extended from a bottom surface of the second head portion toward the first substrate.

In some implementations, a semiconductor memory device include a cell chip, a core/peripheral chip on the cell chip, and a pad on the core/peripheral chip. The cell chip may include a first substrate, word lines buried in the first substrate to be parallel to each other, bit lines disposed on the first substrate to cross the word lines and be parallel to each other, a first interlayer insulating layer provided on the first substrate to cover the word lines and the bit lines, and first interconnection lines provided in the first interlayer insulating layer. The core/peripheral chip may include a second substrate, transistors provided on an active surface of the second substrate, a second interlayer insulating layer provided on the active surface of the second substrate to cover the transistors, second interconnection lines provided in the second interlayer insulating layer, a contact provided in the second interlayer insulating layer to connect the second interconnection lines to the transistors, a third interlayer insulating layer provided on an inactive surface of the second substrate, a power delivery network pattern provided in the third interlayer insulating layer, an inner penetration via provided to penetrate the second substrate and connect the transistors to the power delivery network pattern, and third interconnection lines provided in the third interlayer insulating layer. The first interlayer insulating layer and the second interlayer insulating layer may be in direct contact with each other. The pads may be provided to penetrate the third interlayer insulating layer and may be coupled to the third interconnection lines. The power delivery network and the third interconnection lines may be connected to each other through a penetration via penetrating the third interlayer insulating layer.

### BRIEF DESCRIPTION OF THE DRAWINGS

FIG. 1 is a block diagram illustrating an example of a semiconductor memory device.

FIG. 2 is a perspective view illustrating an example of a semiconductor memory device.

FIG. 3A is a sectional view illustrating an example of a semiconductor memory device.

FIG. 3B is an example enlarged sectional view illustrating a portion ‘A’ of FIG. 3A.

FIG. 4A is a sectional view illustrating an example of a semiconductor memory device.

FIG. 4B is an example enlarged sectional view illustrating a portion ‘B’ of FIG. 4A.

FIG. 5A is a sectional view illustrating an example of a semiconductor memory device.

FIG. 5B is an example enlarged sectional view illustrating a portion ‘C’ of FIG. 5A.

FIG. 6A is a sectional view illustrating an example of a semiconductor memory device.

FIG. 6B is an example enlarged sectional view illustrating a portion ‘D’ of FIG. 6A.

FIG. 7 is a sectional view illustrating an example of a semiconductor memory device.

FIG. 8 is a sectional view illustrating an example of a plurality of semiconductor memory devices.

FIGS. 9 and 10 are sectional views illustrating an example of a semiconductor package including a semiconductor memory device.

FIGS. 11 to 23 are sectional views illustrating an example of a method of fabricating a semiconductor memory device.

### DETAILED DESCRIPTION

Example implementations of the present disclosure will now be described more fully with reference to the accompanying drawings, in which example implementations are shown.

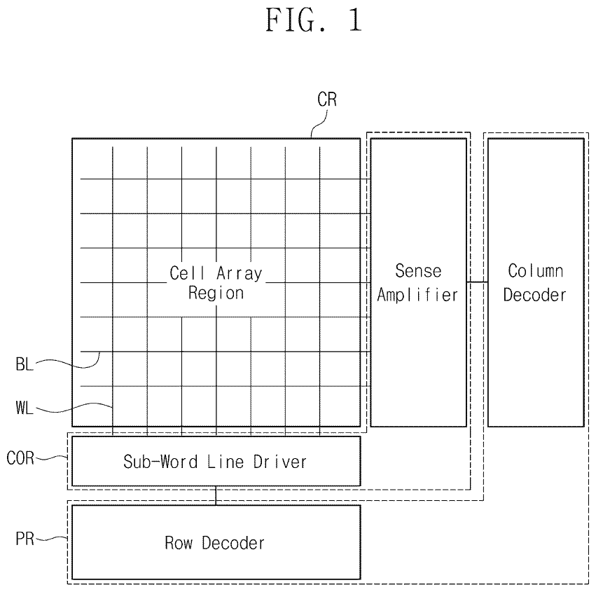

FIG. 1 is a block diagram of an example of a semiconductor memory device.

Referring to FIG. 1, the semiconductor memory device may be, for example, a dynamic random access memory (DRAM) device. The semiconductor memory device may include a cell array region CR. Word lines WL and bit lines BL, which are disposed to cross each other, may be disposed in the cell array region CR.

A core region COR may be disposed near the cell array region CR. A sub-word line driver and a sensing amplifier may be disposed in the core region COR. The sub-word line driver may be configured to select a specific word line in response to a row address signal or a refresh address signal. In the case where an amount of charges stored in a cell capacitor of a selected memory cell is very small, it may be difficult to directly produce a digital signal, which will be output to the outside, from the stored charges, and in this situation, the sensing amplifier may be configured to execute the function of amplifying a signal produced by a small charge amount.

A peripheral circuit region PR may be disposed near the core region COR. A row decoder and a column decoder may be disposed in the peripheral circuit region PR. A structure including the core region COR and the peripheral circuit region PR may be referred to as a logic region. The row decoder may be configured to decode the row address signal or the refresh address signal. The column decoder may be configured to decode a column address signal and execute an operation of selecting the bit line BL, based on the decoded column address information.

The core region COR and the peripheral circuit region PR may constitute a logic region for driving the cell array region CR.

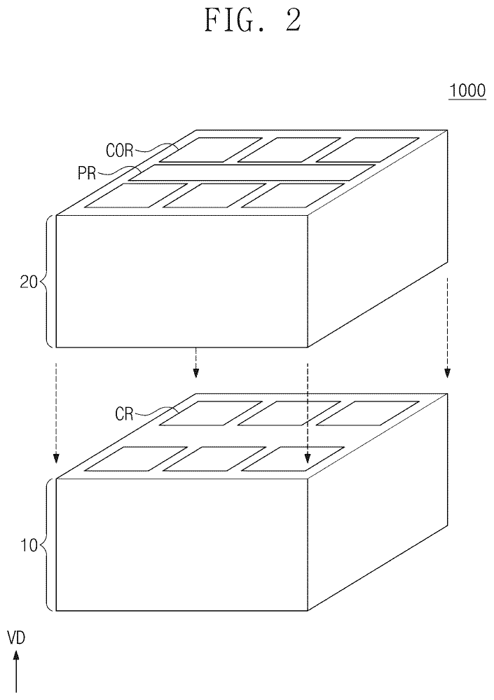

FIG. 2 is a perspective view illustrating an example of a semiconductor memory device.

Referring to FIG. 2, a memory chip 1000 may include a cell chip 10 and a core/peripheral chip 20, which are spaced apart from each other in a vertical direction VD. The cell chip 10 and the core/peripheral chip 20 may be vertically overlapped with each other. As shown in FIG. 2, the core/peripheral chip 20 may be stacked on the cell chip 10.

When viewed in a plan view, the cell chip 10 may include the cell array regions CR. The cell array regions CR may be adjacent to each other in a horizontal direction. Each of the cell array regions CR may be vertically overlapped with at least a portion of each of core regions COR, which will be described below. Each of the cell array regions CR may include a memory cell layer 110, which will be described below, and here, the memory cell layer 110 may be configured to store data therein.

The core/peripheral chip 20 may include the core regions COR and the peripheral circuit region PR, when viewed in a plan view. The core regions COR and the peripheral circuit region PR may be adjacent to each other in a horizontal direction. Each of the core regions COR may include a core bank, and the core bank may include core circuits, such as a sub-word line driver, a sensing amplifier, a row decoder, a column decoder, and a read/write circuit. The peripheral circuit region PR may include peripheral circuits, such as a timing register, an address register, a data input register, a data output register, and a data input/output terminal. The core regions COR and the peripheral circuit region PR may include a core/peripheral transistor 210, which will be described below.

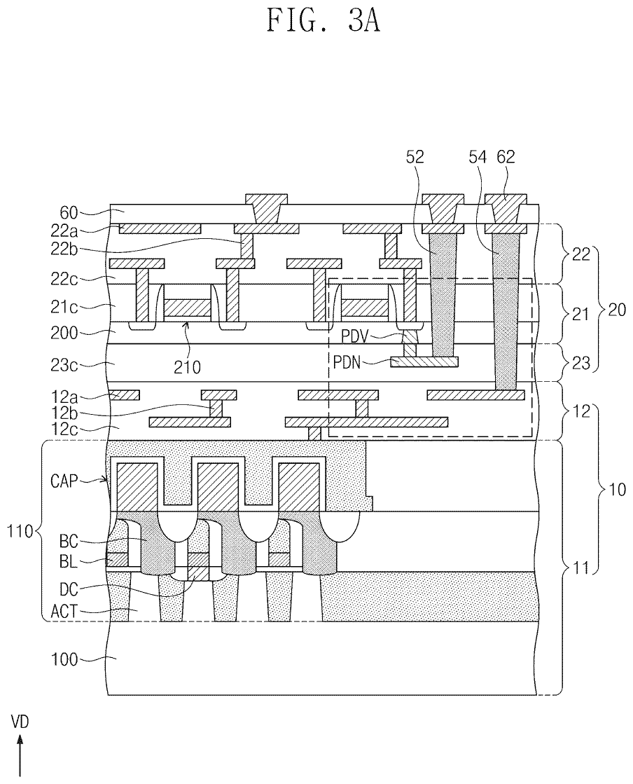

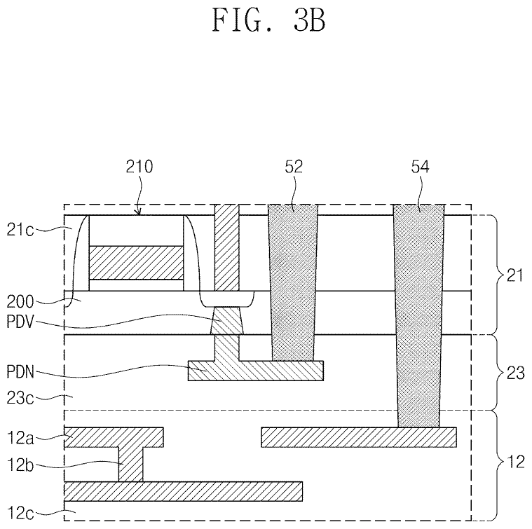

FIG. 3A is a sectional view illustrating an example of a semiconductor memory device. FIG. 3B is an example enlarged sectional view illustrating a portion ‘A’ of FIG. 3A.

Referring to FIGS. 3A and 3B, the cell chip 10 may include a data storing layer 11 and a cell interconnection layer 12. The data storing layer 11 may include a cell semiconductor layer 100 and a memory cell layer 110. The cell semiconductor layer 100 may include a top surface and a bottom surface, which are opposite to each other in the vertical direction VD. The top surface of the cell semiconductor layer 100 may be a front surface of the cell semiconductor layer 100, and the memory cell layer 110 may be formed on the front surface of the cell semiconductor layer 100. The bottom surface of the cell semiconductor layer 100 may be a rear surface of the cell semiconductor layer 100. In the present specification, the term ‘front surface’ may be defined as a surface of a semiconductor chip, on which integrated device, interconnection lines, or pads are formed, and the term ‘rear surface’ may be defined as a surface that is opposite to the front surface of the semiconductor chip. That is, the top surface of the cell semiconductor layer 100 may be an active surface of the cell semiconductor layer 100, and the bottom surface of the cell semiconductor layer 100 may be an inactive surface of the cell semiconductor layer 100.

The cell semiconductor layer 100 may include a semiconductor material. As an example, the cell semiconductor layer 100 may be a semiconductor substrate (e.g., a single crystalline silicon substrate, a silicon-germanium substrate, a silicon-on-insulator (SOI) substrate) that is formed of or includes a semiconductor material. As another example, the cell semiconductor layer 100 may be a semiconductor epitaxial layer including a semiconductor material.

The memory cell layer 110 may include at least one of various types of memory semiconductors. As an example, the memory cell layer 110 may include a two-dimensional memory device (e.g., DRAM devices having a buried channel array transistor (BCAT) type or a vertical channel transistor (VCT) type). As another example, the memory cell layer 110 may include a three-dimensional memory device, such as a vertically-stacked DRAM (VS DRAM) device, a three-dimensional ferroelectric FET (3D FeFET) device, and a 3D monolithic device. For example, the memory cell layer 110 may include a BCAT-type DRAM device, which includes an active region ACT, a bit line node contact DC, a bit line BL, a storage node contact BC, and a capacitor CAP, as shown in FIG. 3A. Here, a word line may be provided below a top surface of the active region ACT to cross the active region ACT. The memory cell layer 110 may constitute the cell array regions CR described with reference to FIG. 2 and may be used to store data therein.

Alternatively, the memory cell layer 110 may include a VCT-type DRAM device, which includes a bit line, a channel pattern, a word line, and a capacitor. Here, the channel pattern may be formed of or include at least one of single-crystalline silicon, poly-crystalline silicon, oxide semiconductor materials (e.g., InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, Sn_{X}O, HfₓIn_{y}Zn_{z}O, GaₓZn_{y}Sn_{z}O, AlₓZn_{y}Sn_{z}O, YbₓGa_{y}Zn_{z}O, and InₓGa_{y}O), two-dimensional materials (e.g., graphene), or a transition metal dichalcogenide (TMD) including a transition metal element (e.g., Mo, W, V, Nb, Ta, or Ti) and a chalcogen element (S, Se, or Te).

The memory cell layer 110 and the cell interconnection layer 12 may be sequentially provided on the top surface of the cell semiconductor layer 100.

The cell interconnection layer 12 may be disposed on the data storing layer 11. The cell interconnection layer 12 may include cell circuit interconnection lines 12a, cell contact plugs 12b, which are used to electrically connect the memory cell layer 110 to the cell circuit interconnection lines 12a, and a first interlayer insulating layer 12c.

The memory cell layer 110 may be covered with the first interlayer insulating layer 12c. The first interlayer insulating layer 12c may have a single- or multi-layered structure, which includes at least one of silicon oxide (SiO), silicon nitride (SiN), silicon oxynitride (SiON), silicon carbonitride (SiCN), or porous insulating materials.

Interconnection lines, which are electrically connected to the memory cell layer 110, may be disposed in the first interlayer insulating layer 12c. The interconnection lines may include cell interconnection patterns 12a and 12b, which are buried in the first interlayer insulating layer 12c. For example, the cell interconnection patterns 12a and 12b may include the cell circuit interconnection lines 12a, which are used for horizontal interconnection, and the cell contact plugs 12b, which are used for vertical interconnection. The cell interconnection patterns 12a and 12b may vertically penetrate the first interlayer insulating layer 12c and may be connected to the memory cell layer 110 (e.g., the capacitor CAP of the memory cell layer 110). The cell interconnection patterns 12a and 12b may be placed between top and bottom surfaces of the first interlayer insulating layer 12c. The cell interconnection patterns 12a and 12b may be formed of or include, for example, copper (Cu) or tungsten (W).

The cell interconnection patterns 12a and 12b may have a damascene structure. For example, the cell interconnection patterns 12a and 12b may include a head portion and a tail portion, which are connected to form a single object. The cell circuit interconnection lines 12a may be the head portion of the cell interconnection patterns 12a and 12b, and the cell contact plugs 12b may be the tail portion of the cell interconnection patterns 12a and 12b. The head and tail portions of the cell interconnection patterns 12a and 12b may have a ‘T’-shaped section.

The head portion of the cell interconnection patterns 12a and 12b (i.e., the cell circuit interconnection lines 12a) may be an interconnection portion or a pad portion horizontally expanding an interconnection line in the cell interconnection layer 12. The cell circuit interconnection lines 12a may not be exposed to the outside of the first interlayer insulating layer 12c through the top surface of the first interlayer insulating layer 12c.

The tail portion of the cell interconnection patterns 12a and 12b (i.e., the cell contact plugs 12b) may be a via portion, which is used to vertically connect the interconnection lines in the cell interconnection layer 12 to each other. The tail portion may be extended from a bottom surface of the head portion and may be coupled to a top surface of another cell circuit interconnection line 12a thereunder or the capacitor CAP.

The core/peripheral chip 20 may be disposed on the cell chip 10. The core/peripheral chip 20 may include a driving layer 21, a core/peripheral interconnection layer 22, and a back-side interconnection layer 23. The core/peripheral interconnection layer 22 may be provided on the driving layer 21.

The driving layer 21 may include a core/peripheral semiconductor layer 200 and a core/peripheral transistor 210 on the core/peripheral semiconductor layer 200. The core/peripheral semiconductor layer 200 may include a top surface and a bottom surface, which are opposite to each other in the vertical direction VD. The top surface of the core/peripheral semiconductor layer 200 may be a front surface of the core/peripheral semiconductor layer 200, and the core/peripheral transistor 210 may be formed on the front surface of the core/peripheral semiconductor layer 200. The bottom surface of the core/peripheral semiconductor layer 200 may be a rear surface of the core/peripheral semiconductor layer 200. That is, the top surface of the core/peripheral semiconductor layer 200 may be an active surface of the cell semiconductor layer 100, and the bottom surface of the cell semiconductor layer 100 may be an inactive surface of the core/peripheral semiconductor layer 200.

The core/peripheral semiconductor layer 200 may include a semiconductor material. As an example, the core/peripheral semiconductor layer 200 may be a semiconductor substrate (e.g., a single crystalline silicon substrate, a silicon-germanium substrate, a silicon-on-insulator (SOI) substrate) that is formed of or includes a semiconductor material. As another example, the core/peripheral semiconductor layer 200 may be a semiconductor epitaxial layer including a semiconductor material.

The core/peripheral transistor 210 may be used as a part of a core circuit, a peripheral circuit, and an NPU. As shown in FIG. 3A, the core/peripheral transistor 210 may include source and drain electrodes, which are provided in an upper portion of the core/peripheral semiconductor layer 200, a gate electrode, which is provided between the source and drain electrodes and on the front surface of the core/peripheral semiconductor layer 200, and a gate insulating layer interposed between the core/peripheral semiconductor layer 200 and the gate electrode. The core/peripheral transistor 210 may be illustrated as a planar-type transistor, as shown in FIG. 3A, but transistors of various structures may be used as the core/peripheral transistor 210. In some implementations, a plurality of core/peripheral transistors 210 may be provided to constitute an integrated circuit. The core/peripheral transistors 210 may constitute the core regions COR or the peripheral circuit region PR described with reference to FIG. 2.

The driving layer 21 may further include a second interlayer insulating layer 21c. The second interlayer insulating layer 21c may cover the core/peripheral transistor 210, on the core/peripheral semiconductor layer 200. In FIG. 3A, the second interlayer insulating layer 21c is illustrated to expose a top surface of the core/peripheral transistor 210 near a top surface thereof, but the concept is not limited to this example. The second interlayer insulating layer 21c may have a single- or multi-layered structure, which includes at least one of silicon oxide (SiO), silicon nitride (SiN), silicon oxynitride (SiON), silicon carbonitride (SiCN), or porous insulating materials.

The driving layer 21 and the core/peripheral interconnection layer 22 may be sequentially provided on the top surface of the core/peripheral semiconductor layer 200.

The core/peripheral interconnection layer 22 may be disposed on the driving layer 21. The core/peripheral interconnection layer 22 may include core/peripheral circuit interconnection lines 22a, core/peripheral contact plugs 22b, which are used to electrically connect the core/peripheral transistor 210 to the core/peripheral circuit interconnection lines 22a, and a third interlayer insulating layer 22c.

The driving layer 21 may be covered with the third interlayer insulating layer 22c. The third interlayer insulating layer 22c may have a single- or multi-layered structure, which includes at least one of silicon oxide (SiO), silicon nitride (SIN), silicon oxynitride (SiON), silicon carbonitride (SiCN), or porous insulating materials.

Interconnection lines, which are electrically connected to the core/peripheral transistor 210, may be disposed in the third interlayer insulating layer 22c. The interconnection lines may include the core/peripheral interconnection patterns 22a and 22b, which are buried in the third interlayer insulating layer 22c. For example, the core/peripheral interconnection patterns 22a and 22b may include the core/peripheral circuit interconnection lines 22a, which are used for horizontal interconnection, and the core/peripheral contact plugs 22b, which are used for vertical interconnection. The core/peripheral interconnection patterns 22a and 22b may vertically penetrate the third interlayer insulating layer 22c and may be connected to the driving layer 21 (e.g., one of source, drain, and gate electrodes of the core/peripheral transistor 210). The core/peripheral interconnection patterns 22a and 22b may be placed between top and bottom surfaces of the third interlayer insulating layer 22c. The core/peripheral interconnection patterns 22a and 22b may be formed of or include, for example, copper (Cu) or tungsten (W).

The core/peripheral interconnection patterns 22a and 22b may have a damascene structure. For example, the core/peripheral interconnection patterns 22a and 22b may include a head portion and a tail portion, which are connected to form a single object. The core/peripheral circuit interconnection lines 22a may be the head portion of the core/peripheral interconnection patterns 22a and 22b, and the core/peripheral contact plugs 22b may be the tail portion of the core/peripheral interconnection patterns 22a and 22b. The head and tail portions of the core/peripheral interconnection patterns 22a and 22b may have a ‘T’-shaped section.

The head portion of the core/peripheral interconnection patterns 22a and 22b (i.e., the core/peripheral circuit interconnection lines 22a) may be an interconnection portion or a pad portion horizontally expanding an interconnection line in the core/peripheral interconnection layer 22. At least one of the core/peripheral circuit interconnection lines 22a may be exposed to the outside of the third interlayer insulating layer 22c through the top surface of the third interlayer insulating layer 22c. Alternatively, the core/peripheral circuit interconnection lines 22a may not be exposed through the top surface of the third interlayer insulating layer 22c and may be buried in the third interlayer insulating layer 22c.

The tail portion of the core/peripheral interconnection patterns 22a and 22b (i.e., the core/peripheral contact plugs 22b) may be a via portion, which is used to vertically connect the interconnection lines in the core/peripheral interconnection layer 22 to each other. The tail portion may be extended from a bottom surface of the head portion and may be coupled to a top surface of another cell circuit interconnection line 12a thereunder. In some implementations, the tail portion may be extended from the bottom surface of the head portion to penetrate the third interlayer insulating layer 22c and the second interlayer insulating layer 21c and may be coupled to the core/peripheral transistor 210.

The back-side interconnection layer 23 may be disposed below the core/peripheral semiconductor layer 200. For example, the back-side interconnection layer 23 may be disposed on the rear surface of the core/peripheral semiconductor layer 200 (i.e., the bottom surface of the core/peripheral semiconductor layer 200). The back-side interconnection layer 23 may include a power delivery network pattern PDN and a fourth interlayer insulating layer 23c.

The rear surface of the core/peripheral semiconductor layer 200 may be covered with the fourth interlayer insulating layer 23c. The fourth interlayer insulating layer 23c may have a single- or multi-layered structure, which includes at least one of silicon oxide (SiO), silicon nitride (SiN), silicon oxynitride (SiON), silicon carbonitride (SiCN), or porous insulating materials.

A power delivery network pattern PDN may be disposed in the fourth interlayer insulating layer 23c. The power delivery network pattern PDN may be an interconnection pattern, which is used to supply a power signal to the core/peripheral transistor 210. The power delivery network pattern PDN may be buried in the fourth interlayer insulating layer 23c. The power delivery network pattern PDN may be placed between top and bottom surfaces of the fourth interlayer insulating layer 23c. The power delivery network pattern PDN may be formed of or include, for example, copper (Cu) or tungsten (W).

The power delivery network pattern PDN may have a damascene structure. For example, the power delivery network pattern PDN may include a head portion and a tail portion, which are connected to form a single object. The head and tail portions of the power delivery network pattern PDN may be provided to have an inverted shape of the letter ‘T’, when viewed in a sectional view.

The head portion of the power delivery network pattern PDN may be an interconnection portion or a pad portion horizontally expanding an interconnection line in the back-side interconnection layer 23. The power delivery network pattern PDN may not be exposed to the outside of the fourth interlayer insulating layer 23c through a bottom surface of the fourth interlayer insulating layer 23c.

The tail portion of the power delivery network pattern PDN may be a via portion, which is used to vertically connect the interconnection lines in the back-side interconnection layer 23 to each other. The tail portion of the power delivery network pattern PDN may be extended from a top surface of the head portion to penetrate the fourth interlayer insulating layer 23c and may be coupled to the rear surface of the core/peripheral semiconductor layer 200.

The power delivery network pattern PDN may be electrically coupled to the core/peripheral transistor 210. For example, an inner penetration via PDV may be provided in the core/peripheral semiconductor layer 200. The inner penetration via PDV may be provided to vertically penetrate the core/peripheral semiconductor layer 200. The inner penetration via PDV may be exposed to the outside of the core/peripheral semiconductor layer 200 through the bottom surface of the core/peripheral semiconductor layer 200. The tail portion of the power delivery network pattern PDN may be coupled to a bottom surface of the inner penetration via PDV. The inner penetration via PDV may be vertically extended to be connected to the core/peripheral transistor 210. For example, in the core/peripheral semiconductor layer 200, the inner penetration via PDV may be directly coupled to a source electrode of the core/peripheral transistor 210. The inner penetration via PDV may be formed of or include at least one of metallic materials (e.g., copper (Cu)).

FIG. 3A illustrates an example in which one core/peripheral transistor 210 is coupled to the power delivery network pattern PDN through one inner penetration via PDV, but the concept is not limited to this example. The power delivery network pattern PDN may be configured to deliver or distribute a power signal to the core/peripheral chip 20. For example, each of the core/peripheral transistors 210 may be connected to a corresponding one of the inner penetration vias PDV, and the inner penetration vias PDV may be coupled to the power delivery network pattern PDN to receive the power signal. In other words, the core/peripheral interconnection layer 22 may be used to deliver an operation signal for the core/peripheral transistor 210 to the driving layer 21, and the back-side interconnection layer 23 may be used to deliver the power signal for the core/peripheral transistor 210 to the driving layer 21.

A first passivation layer 60 may be provided on the third interlayer insulating layer 22c of the core/peripheral interconnection layer 22. The first passivation layer 60 may cover the third interlayer insulating layer 22c and the core/peripheral interconnection patterns 22a and 22b. The first passivation layer 60 may be formed of or include at least one of silicon oxide (SiO), silicon nitride (SiN), silicon oxynitride (SiON), silicon carbonitride (SiCN), insulating polymers, or photoimageable polymers.

Chip pads 62 may be provided on a top surface of the first passivation layer 60. The chip pads 62 may vertically penetrate the first passivation layer 60 and may be coupled to the core/peripheral interconnection patterns 22a and 22b. The core/peripheral interconnection patterns 22a and 22b may be used to deliver an operation signal, which is transferred from the chip pads 62, to the core/peripheral transistor 210. The chip pads 62 may be formed of or include at least one of metallic materials (e.g., copper (Cu)).

The power delivery network pattern PDN may receive a power signal from the chip pads 62. For example, a first outer penetration via 52 may be provided in the core/peripheral chip 20. The first outer penetration via 52 may be provided in a region adjacent to the core/peripheral transistor 210 to vertically penetrate the third interlayer insulating layer 22c, the second interlayer insulating layer 21c, the core/peripheral semiconductor layer 200, and the fourth interlayer insulating layer 23c. An end of the first outer penetration via 52 may be coupled to the power delivery network pattern PDN, in the fourth interlayer insulating layer 23c. An opposite end of the first outer penetration via 52 may be coupled to the core/peripheral circuit interconnection lines 22a, in the third interlayer insulating layer 22c. The power delivery network pattern PDN may be configured to receive the power signal through the chip pads 62, the core/peripheral circuit interconnection lines 22a, and the first outer penetration via 52, and moreover, the power delivery network pattern PDN may be used to supply and distribute the power signal to at least one of the core/peripheral transistors 210 through the inner penetration via PDV or the inner penetration vias PDV. The first outer penetration via 52 may be formed of or include at least one of metallic materials (e.g., copper (Cu) or tungsten (W)).

In some implementations, the core/peripheral interconnection layer 22, which is used to deliver an operation signal in the core/peripheral chip 20, may be provided on the front surface of the core/peripheral semiconductor layer 200, and the back-side interconnection layer 23, which is used to deliver the power signal, may be provided on the rear surface of the core/peripheral semiconductor layer 200. That is, interconnection lines, which are used to drive the core/peripheral chip 20, may be disposed on the front and rear surfaces of the core/peripheral semiconductor layer 200 in a vertically-separated manner. Thus, it may be possible to reduce a planar area for the interconnection line in the core/peripheral chip 20 and thereby to reduce a size of the semiconductor memory device. In addition, an interconnection density may be lowered in each of the core/peripheral interconnection layer 22 and the back-side interconnection layer 23, and this may prevent technical issues (e.g., parasitic capacitance or short circuit), which may occur when the interconnection density is high. That is, in some implementations, it may be possible to improve the electrical characteristics of the semiconductor memory device.

The core/peripheral chip 20 may be disposed on the cell chip 10. The core/peripheral chip 20 may be in direct contact with the cell chip 10.

At an interface between the cell chip 10 and the core/peripheral chip 20, the first interlayer insulating layer 12c of the cell chip 10 may be bonded to the fourth interlayer insulating layer 23c of the core/peripheral chip 20. Here, the first interlayer insulating layer 12c and the fourth interlayer insulating layer 23c may form a hybrid bonding structure of oxide, nitride, or oxynitride. In the present specification, the hybrid bonding structure may mean a bonding structure that is formed by two materials, which are of the same kind and are fused at an interface therebetween. For example, the first interlayer insulating layer 12c and the fourth interlayer insulating layer 23c, which are bonded to each other, may have a continuous structure, and in this case, there may be no visible interface between the first interlayer insulating layer 12c and the fourth interlayer insulating layer 23c, as shown in FIG. 3B. For example, the first interlayer insulating layer 12c and the fourth interlayer insulating layer 23c may be formed of the same material, and in this case, there may be no interface between the first interlayer insulating layer 12c and the fourth interlayer insulating layer 23c. That is, the first interlayer insulating layer 12c and the fourth interlayer insulating layer 23c may be provided as a single element. For example, the first interlayer insulating layer 12c and the fourth interlayer insulating layer 23c may be bonded to form a single object. However, the concept is not limited to this example. The first interlayer insulating layer 12c and the fourth interlayer insulating layer 23c may be formed of different materials. The first interlayer insulating layer 12c and the fourth interlayer insulating layer 23c may not have a continuous structure, and there may be a visible interface between the first interlayer insulating layer 12c and the fourth interlayer insulating layer 23c. The first interlayer insulating layer 12c and the fourth interlayer insulating layer 23c may not be bonded to each other and may be separately provided as individual elements.

In some implementations, since the first interlayer insulating layer 12c of the cell chip 10 is directly bonded to the fourth interlayer insulating layer 23c of the core/peripheral chip 20 through a hybrid bonding structure, the cell chip 10 and the core/peripheral chip 20 may be robustly bonded to each other. In some implementations, it may be possible to improve the structural stability of the semiconductor memory device.

A second outer penetration via 54 may be provided in the core/peripheral chip 20. The second outer penetration via 54 may be provided in a region adjacent to the core/peripheral transistor 210 to vertically penetrate the third interlayer insulating layer 22c, the second interlayer insulating layer 21c, the core/peripheral semiconductor layer 200, the fourth interlayer insulating layer 23c, and the first interlayer insulating layer 12c. An end of the second outer penetration via 54 may be coupled to the cell circuit interconnection lines 12a, in the first interlayer insulating layer 12c. An opposite end of the second outer penetration via 54 may be coupled to the core/peripheral circuit interconnection lines 22a, in the third interlayer insulating layer 22c. The memory cell layer 110 may receive the power signal or input/output signal through the chip pads 62, the core/peripheral circuit interconnection lines 22a, the second outer penetration via 54, and the cell circuit interconnection lines 12a. The second outer penetration via 54 may be formed of or include at least one of metallic materials (e.g., copper (Cu) or tungsten (W)).

In the description of the implementations to be explained below, an element previously described with reference to FIGS. 3A and 3B may be identified by the same reference number without repeating an overlapping description thereof, for concise description.

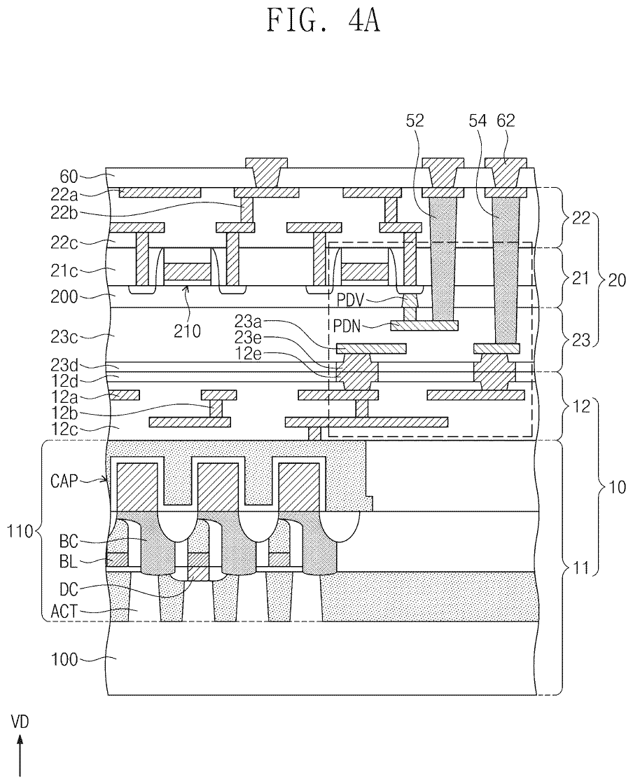

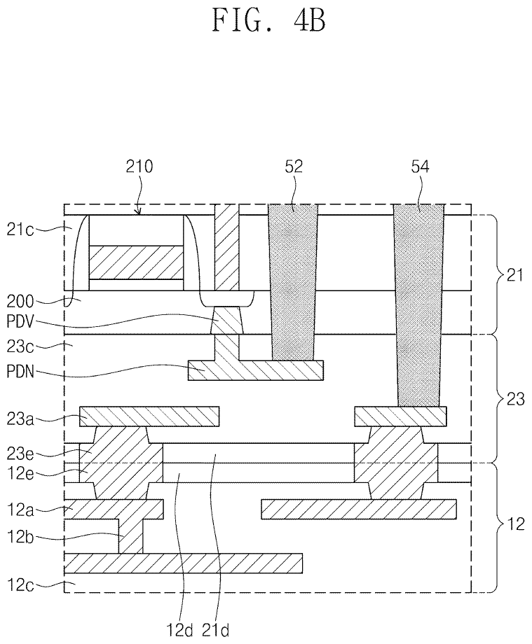

FIG. 4A is a sectional view illustrating an example of a semiconductor memory device. FIG. 4B is an example enlarged sectional view illustrating a portion ‘B’ of FIG. 4A.

Referring to FIGS. 4A and 4B, the cell interconnection layer 12 of the cell chip 10 may further include a second passivation layer 12d and first inner pads 12e.

The first inner pads 12e may be provided on a top surface of the first interlayer insulating layer 12c. The first inner pads 12e may vertically penetrate the first interlayer insulating layer 12c and may be coupled to the cell interconnection patterns 12a and 12b. The cell interconnection patterns 12a and 12b may be used to transmit the power signal or the input/output signal, which is transferred from the first inner pads 12e, to the memory cell layer 110. The first inner pads 12e may be formed of or include at least one of metallic materials (e.g., copper (Cu)).

The second passivation layer 12d may cover the first interlayer insulating layer 12c. The second passivation layer 12d may be provided on the top surface of the first interlayer insulating layer 12c to enclose the first inner pads 12e. Here, a top surface of the second passivation layer 12d may be substantially coplanar with top surfaces of the first inner pads 12e and may be substantially flat. The second passivation layer 12d may be formed of or include at least one of silicon oxide (SiO), silicon nitride (SiN), silicon oxynitride (SiON), silicon carbonitride (SiCN), insulating polymers, or photoimageable polymers.

The back-side interconnection layer 23 of the core/peripheral chip 20 may further include back-side interconnection lines 23a. The back-side interconnection lines 23a may be buried in the fourth interlayer insulating layer 23c. The back-side interconnection lines 23a may be used for horizontal interconnection. The back-side interconnection lines 23a may be formed of or include, for example, copper (Cu) or tungsten (W).

The second outer penetration via 54 may be provided in a region adjacent to the core/peripheral transistor 210 to vertically penetrate the third interlayer insulating layer 22c, the second interlayer insulating layer 21c, the core/peripheral semiconductor layer 200, and the fourth interlayer insulating layer 23c. An end of the second outer penetration via 54 may be coupled to the back-side interconnection lines 23a, in the fourth interlayer insulating layer 23c. An opposite end of the second outer penetration via 54 may be coupled to the core/peripheral circuit interconnection lines 22a, in the third interlayer insulating layer 22c.

The back-side interconnection layer 23 of the core/peripheral chip 20 may further include a third passivation layer 23d and second inner pads 23e.

The second inner pads 23e may be provided on the bottom surface of the fourth interlayer insulating layer 23c. The second inner pads 23e may vertically penetrate the fourth interlayer insulating layer 23c and may be coupled to the back-side interconnection lines 23a. The second inner pads 23e may be formed of or include at least one of metallic materials (e.g., copper (Cu)).

The third passivation layer 23d may cover the fourth interlayer insulating layer 23c. The third passivation layer 23d may enclose the second inner pads 23e, on the bottom surface of the fourth interlayer insulating layer 23c. Here, a bottom surface of the third passivation layer 23d may be substantially coplanar with bottom surfaces of the second inner pads 23e and may be substantially flat. The third passivation layer 23d may be formed of or include at least one of silicon oxide (SiO), silicon nitride (SiN), silicon oxynitride (SiON), silicon carbonitride (SiCN), insulating polymers, or photoimageable polymers.

The core/peripheral chip 20 may be disposed on the cell chip 10. The cell chip 10 may be disposed such that the first inner pads 12e are adjacent to the core/peripheral chip 20. The first inner pads 12e of the cell chip 10 may be vertically aligned to the second inner pads 23e of the core/peripheral chip 20. The cell chip 10 and the core/peripheral chip 20 may be in contact with each other.

At the interface between the cell chip 10 and the core/peripheral chip 20, the second passivation layer 12d of the cell chip 10 may be bonded to the third passivation layer 23d of the core/peripheral chip 20. Here, the second passivation layer 12d and the third passivation layer 23d may form a hybrid bonding structure of oxide, nitride, or oxynitride. For example, the second passivation layer 12d and the third passivation layer 23d, which are bonded to each other, may have a continuous structure, and in this case, there may be no visible interface between the second passivation layer 12d and the third passivation layer 23d. That is, the second passivation layer 12d and the third passivation layer 23d may be provided as a single element. However, the concept is not limited to this example. The second passivation layer 12d and the third passivation layer 23d may be formed of different materials. The second passivation layer 12d and the third passivation layer 23d may not have a continuous structure, and there may be a visible interface between the second passivation layer 12d and the third passivation layer 23d.

The cell chip 10 and the core/peripheral chip 20 may be connected to each other. For example, the cell chip 10 and the core/peripheral chip 20 may be in contact with each other at the interface between the cell chip 10 and the core/peripheral chip 20, the first inner pads 12e of the cell chip 10 may be bonded to the second inner pads 23e of the core/peripheral chip 20. In more detail, the first inner pads 12e and the second inner pads 23e may form an intermetal hybrid bonding structure. For example, the first inner pads 12e and the second inner pads 23e, which are bonded to each other, may have a continuous structure, and in this case, there may be no visible interface between the first inner pads 12e and the second inner pads 23e, as shown in FIG. 4B. That is, the first inner pads 12e and the second inner pads 23e may be provided as a single element.

The memory cell layer 110 may receive the power signal or the input/output signal through the chip pads 62, the core/peripheral circuit interconnection lines 22a, the second outer penetration via 54, the back-side interconnection lines 23a, the second inner pads 23e, the first inner pads 12e, and the cell circuit interconnection lines 12a.

FIGS. 3A, 3B, 4A, and 4B illustrate an example, in which the cell interconnection layer 12 of the cell chip 10 is in contact with the back-side interconnection layer 23 of the core/peripheral chip 20, but the concept is not limited to this example.

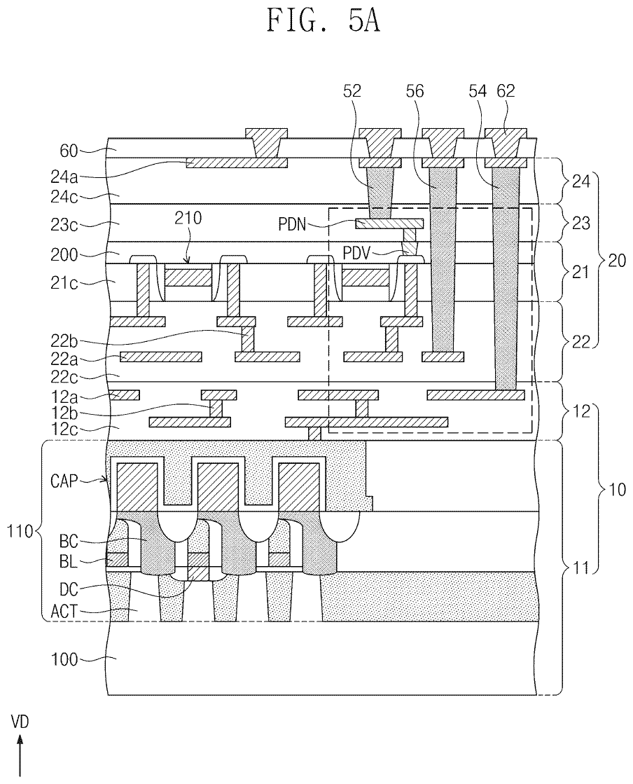

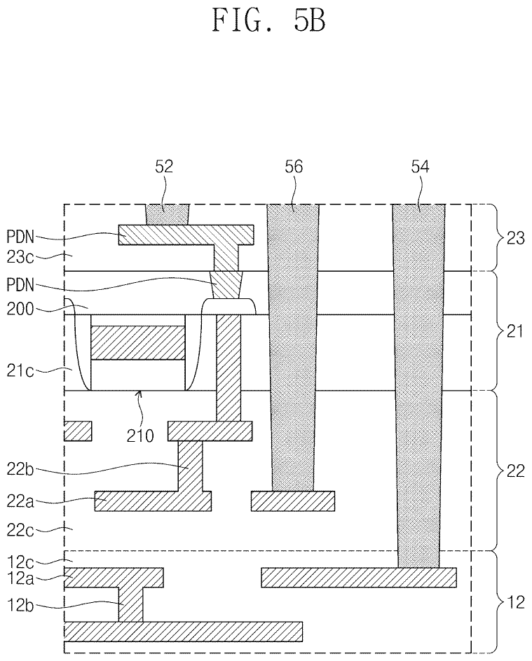

FIG. 5A is a sectional view illustrating an example of a semiconductor memory device. FIG. 5B is an example enlarged sectional view illustrating a portion ‘C’ of FIG. 5A.

Referring to FIGS. 5A and 5B, the core/peripheral chip 20 may be disposed on the cell chip 10. The core/peripheral chip 20 may include the driving layer 21, the core/peripheral interconnection layer 22, and the back-side interconnection layer 23. The core/peripheral interconnection layer 22 may be provided on the driving layer 21.

The driving layer 21 may include the core/peripheral semiconductor layer 200 and the core/peripheral transistor 210 on the core/peripheral semiconductor layer 200. A bottom surface of the core/peripheral semiconductor layer 200 may be the front surface of the core/peripheral semiconductor layer 200, and the core/peripheral transistor 210 may be formed on the front surface of the core/peripheral semiconductor layer 200. A top surface of the core/peripheral semiconductor layer 200 may be the rear surface of the core/peripheral semiconductor layer 200.

The core/peripheral interconnection layer 22 may be disposed on the front surface of the core/peripheral semiconductor layer 200. The core/peripheral interconnection layer 22 may be disposed on the driving layer 21. The core/peripheral interconnection layer 22 may be placed between the driving layer 21 and the cell chip 10. The core/peripheral interconnection layer 22 may include the core/peripheral circuit interconnection lines 22a, the core/peripheral contact plugs 22b electrically connecting the core/peripheral transistor 210 to the core/peripheral circuit interconnection lines 22a, and the third interlayer insulating layer 22c. The core/peripheral interconnection patterns 22a and 22b may be buried in the third interlayer insulating layer 22c.

The core/peripheral interconnection patterns 22a and 22b may have a damascene structure. For example, the core/peripheral interconnection patterns 22a and 22b may include a head portion and a tail portion, which are connected to form a single object. The core/peripheral circuit interconnection lines 22a may be a head portion of the core/peripheral interconnection patterns 22a and 22b, and the core/peripheral contact plugs 22b may be a tail portion of the core/peripheral interconnection patterns 22a and 22b. The head and tail portions of the core/peripheral interconnection patterns 22a and 22b may be provided to have an inverted shape of the letter ‘T’, when viewed in a sectional view.

The back-side interconnection layer 23 may be disposed on the rear surface of the core/peripheral semiconductor layer 200 (i.e., the top surface of the core/peripheral semiconductor layer 200). The back-side interconnection layer 23 may include the power delivery network pattern PDN and the fourth interlayer insulating layer 23c. The power delivery network pattern PDN may be connected to the core/peripheral transistor 210 through the inner penetration via PDV, which is provided to vertically penetrate the core/peripheral semiconductor layer 200. The power delivery network pattern PDN may have a damascene structure. For example, the power delivery network pattern PDN may include a head portion and a tail portion, which are provided to have a ‘T’-shaped section.

The core/peripheral chip 20 may further include an additional interconnection layer 24. The additional interconnection layer 24 may cover the back-side interconnection layer 23. The additional interconnection layer 24 may include additional interconnection lines 24a and a fifth interlayer insulating layer 24c.

The fifth interlayer insulating layer 24c may cover a top surface of the back-side interconnection layer 23. The fifth interlayer insulating layer 24c may have a single- or multi-layered structure, which includes at least one of silicon oxide (SiO), silicon nitride (SiN), silicon oxynitride (SiON), silicon carbonitride (SiCN), or porous insulating materials.

Interconnection lines, which are electrically connected to the memory cell layer 110, may be disposed in the fifth interlayer insulating layer 24c. The interconnection lines may include the additional interconnection lines 24a, which are provided in the fifth interlayer insulating layer 24c. The additional interconnection lines 24a may be used for horizontal interconnection. In some implementations, unlike the illustrated structure, the interconnection lines may further include contact plugs, which are provided for vertical interconnection. The additional interconnection lines 24a may be placed between top and bottom surfaces of the fifth interlayer insulating layer 24c. The additional interconnection lines 24a may be exposed to the outside of the fifth interlayer insulating layer 24c through the top surface of the fifth interlayer insulating layer 24c. However, the concept is not limited to this example, and in some implementations, the additional interconnection lines 24a may be buried in the fifth interlayer insulating layer 24c. The additional interconnection lines 24a may be formed of or include, for example, copper (Cu) or tungsten (W).

The first passivation layer 60 may be provided on the fifth interlayer insulating layer 24c of the additional interconnection layer 24. The first passivation layer 60 may cover the fifth interlayer insulating layer 24c and the additional interconnection lines 24a.

The chip pads 62 may be provided on the top surface of the first passivation layer 60. The chip pads 62 may vertically penetrate the first passivation layer 60 and may be coupled to the additional interconnection lines 24a.

The core/peripheral chip 20 may be disposed on the cell chip 10. The core/peripheral chip 20 may be in direct contact with the cell chip 10.

At the interface between the cell chip 10 and the core/peripheral chip 20, the first interlayer insulating layer 12c of the cell chip 10 may be bonded to the third interlayer insulating layer 22c of the core/peripheral chip 20. Here, the first interlayer insulating layer 12c and the third interlayer insulating layer 22c may form a hybrid bonding structure of oxide, nitride, or oxynitride. For example, the first interlayer insulating layer 12c and the third interlayer insulating layer 22c, which are bonded to each other, may have a continuous structure, and in this case, there may be no visible interface between the first interlayer insulating layer 12c and the third interlayer insulating layer 22c, as shown in FIG. 5B. For example, the first interlayer insulating layer 12c and the third interlayer insulating layer 22c may be formed of the same material, and in this case, there may be no interface between the first interlayer insulating layer 12c and the third interlayer insulating layer 22c. That is, the first interlayer insulating layer 12c and the third interlayer insulating layer 22c may be provided as a single element. For example, the first interlayer insulating layer 12c and the third interlayer insulating layer 22c may be bonded to form a single object. However, the concept is not limited to this example. The first interlayer insulating layer 12c and the third interlayer insulating layer 22c may be formed of different materials. The first interlayer insulating layer 12c and the third interlayer insulating layer 22c may not have a continuous structure, and there may be a visible interface between the first interlayer insulating layer 12c and the third interlayer insulating layer 22c. The first interlayer insulating layer 12c and the third interlayer insulating layer 22c may not be bonded to each other and may be separately provided as individual elements.

The power delivery network pattern PDN may receive the power signal from the chip pads 62. For example, the first outer penetration via 52 may be provided in the core/peripheral chip 20. The first outer penetration via 52 may be provided on the core/peripheral transistor 210 to vertically penetrate the fifth interlayer insulating layer 24c and the fourth interlayer insulating layer 23c. An end of the first outer penetration via 52 may be coupled to the power delivery network pattern PDN, in the fourth interlayer insulating layer 23c. An opposite end of the first outer penetration via 52 may be coupled to the additional interconnection lines 24a, in the fifth interlayer insulating layer 24c. The power delivery network pattern PDN may be configured to receive the power signal through the chip pads 62, the additional interconnection lines 24a, and the first outer penetration via 52, and moreover, the power delivery network pattern PDN may be used to supply and distribute the power signal to at least one of the core/peripheral transistors 210 through at least one of the inner penetration vias PDV.

The second outer penetration via 54 may be provided in the core/peripheral chip 20. The second outer penetration via 54 may be provided in a region adjacent to the core/peripheral transistor 210 to vertically penetrate the fifth interlayer insulating layer 24c, the fourth interlayer insulating layer 23c, the core/peripheral semiconductor layer 200, the second interlayer insulating layer 21c, the third interlayer insulating layer 22c, and the first interlayer insulating layer 12c. An end of the second outer penetration via 54 may be coupled to the cell circuit interconnection lines 12a, in the first interlayer insulating layer 12c. An opposite end of the second outer penetration via 54 may be coupled to the additional interconnection lines 24a, in the fifth interlayer insulating layer 24c. The memory cell layer 110 may receive the power signal or the input/output signal through the chip pads 62, the additional interconnection lines 24a, the second outer penetration via 54, and the cell circuit interconnection lines 12a.

The core/peripheral chip 20 may further include a third outer penetration via 56. The third outer penetration via 56 may be provided in a region adjacent to the core/peripheral transistor 210 to vertically penetrate the fifth interlayer insulating layer 24c, the fourth interlayer insulating layer 23c, the core/peripheral semiconductor layer 200, the second interlayer insulating layer 21c, and the third interlayer insulating layer 22c. An end of the second outer penetration via 54 may be coupled to the core/peripheral circuit interconnection lines 22a, in the third interlayer insulating layer 22c. An opposite end of the second outer penetration via 54 may be coupled to the additional interconnection lines 24a, in the fifth interlayer insulating layer 24c. The core/peripheral transistor 210 may receive an operation signal through the chip pads 62, the additional interconnection lines 24a, the third outer penetration via 56, and the core/peripheral circuit interconnection lines 22a.

In some implementations, the power delivery network pattern PDN for power supply may be formed in the back-side interconnection layer 23, which is used to transfer a power signal. Here, the power delivery network pattern PDN may be connected to the core/peripheral transistor 210 through the inner penetration via PDV penetrating the core/peripheral semiconductor layer 200. Thus, it may be possible to reduce a length of an electric connection path from the power delivery network pattern PDN to the core/peripheral transistor 210. In addition, since the chip pads 62 are provided on the rear surface of the core/peripheral semiconductor layer 200, it may be possible to reduce a length of an electric connection path from the chip pads 62 to the power delivery network pattern PDN. As a result, it may be possible to improve the electrical characteristics of the semiconductor memory device.

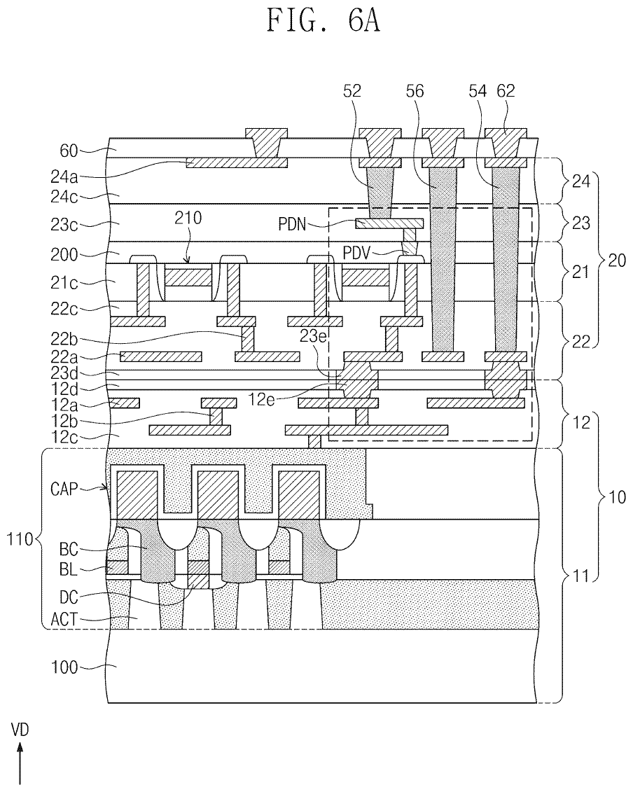

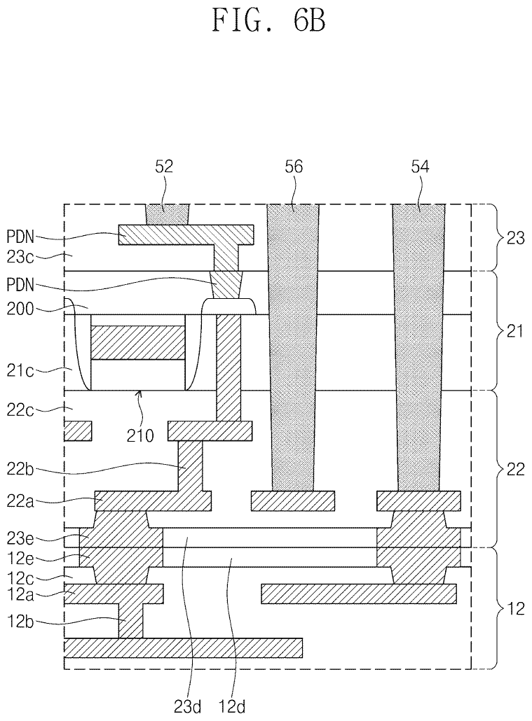

FIG. 6A is a sectional view illustrating an example of a semiconductor memory device. FIG. 6B is an example enlarged sectional view illustrating a portion ‘D’ of FIG. 6A. For concise description, an element previously described with reference to FIGS. 5A and 5B may be identified by the same reference number without repeating an overlapping description thereof.

Referring to FIGS. 6A and 6B, the cell interconnection layer 12 of the cell chip 10 may further include the second passivation layer 12d and the first inner pads 12e.

The first inner pads 12e may be provided on the top surface of the first interlayer insulating layer 12c. The first inner pads 12e may vertically penetrate the first interlayer insulating layer 12c and may be coupled to the cell interconnection patterns 12a and 12b. The cell interconnection patterns 12a and 12b may be used to transmit the power signal or the input/output signal, which is transferred from the first inner pads 12e, to the memory cell layer 110.

The second passivation layer 12d may cover the first interlayer insulating layer 12c. The second passivation layer 12d may be provided on the top surface of the first interlayer insulating layer 12c to enclose the first inner pads 12e. Here, the top surface of the second passivation layer 12d may be substantially coplanar with the top surfaces of the first inner pads 12e and may be substantially flat.

The second outer penetration via 54 may be provided in a region adjacent to the core/peripheral transistor 210 to vertically penetrate the fifth interlayer insulating layer 24c, the fourth interlayer insulating layer 23c, the core/peripheral semiconductor layer 200, the second interlayer insulating layer 21c, and the third interlayer insulating layer 22c. An end of the second outer penetration via 54 may be coupled to the core/peripheral circuit interconnection lines 22a, in the third interlayer insulating layer 22c. An opposite end of the second outer penetration via 54 may be coupled to the additional interconnection lines 24a, in the fifth interlayer insulating layer 24c.

The core/peripheral interconnection layer 22 of the core/peripheral chip 20 may further include the third passivation layer 23d and the second inner pads 23e.

The second inner pads 23e may be provided on a bottom surface of the third interlayer insulating layer 22c. The second inner pads 23e may vertically penetrate the third interlayer insulating layer 22c and may be coupled to the core/peripheral circuit interconnection lines 22a.

The third passivation layer 23d may cover the third interlayer insulating layer 22c. The third passivation layer 23d may be provided on the bottom surface of the third interlayer insulating layer 22c to enclose the second inner pads 23e. Here, the bottom surface of the third passivation layer 23d may be substantially coplanar with the bottom surfaces of the second inner pads 23e and may be substantially flat.

The core/peripheral chip 20 may be disposed on the cell chip 10. The cell chip 10 may be disposed such that the first inner pads 12e face the core/peripheral chip 20. The first inner pads 12e of the cell chip 10 may be vertically aligned to the second inner pads 23e of the core/peripheral chip 20. The cell chip 10 and the core/peripheral chip 20 may be in contact with each other.

At the interface between the cell chip 10 and the core/peripheral chip 20, the second passivation layer 12d of the cell chip 10 may be in contact with the third passivation layer 23d of the core/peripheral chip 20. In some implementations, the second passivation layer 12d and the third passivation layer 23d may form a hybrid bonding structure of oxide, nitride, or oxynitride.

The cell chip 10 and the core/peripheral chip 20 may be connected to each other. For example, the cell chip 10 and the core/peripheral chip 20 may be in contact with each other at the interface between the cell chip 10 and the core/peripheral chip 20, the first inner pads 12e of the cell chip 10 may be bonded to the second inner pads 23e of the core/peripheral chip 20. In more detail, the first inner pads 12e and the second inner pads 23e may form an intermetal hybrid bonding structure. For example, the first inner pads 12e and the second inner pads 23e, which are bonded to each other, may have a continuous structure, and in this case, there may be no visible interface between the first inner pads 12e and the second inner pads 23e, as shown in FIG. 6B. That is, the first inner pads 12e and the second inner pads 23e may be provided as a single element.

The memory cell layer 110 may receive the power signal or input/output signal through the chip pads 62, the additional interconnection lines 24a, the second outer penetration via 54, the core/peripheral circuit interconnection lines 22a, the second inner pads 23e, the first inner pads 12e, and the cell circuit interconnection lines 12a.

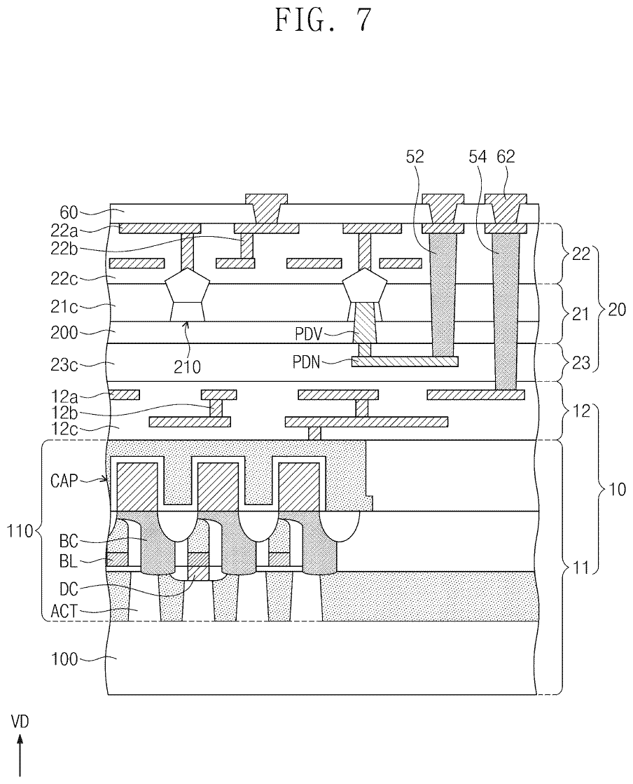

FIG. 7 is a sectional view illustrating an example of a semiconductor memory device.

FIGS. 3A to 6A illustrate an example, in which the core/peripheral transistor 210 is a planar-type transistor, but the concept is not limited to this example. Transistors of various structures may be used as the core/peripheral transistor 210. For example, the core/peripheral transistor 210 may have a three-dimensional structure, as shown in FIG. 7. In some implementations, the core/peripheral transistor 210 may be a Fin-FET. The core/peripheral transistor 210 may include an active pattern, which is extended in a direction on the front surface of the core/peripheral semiconductor layer 200, a gate electrode, which is provided on the front surface of the core/peripheral semiconductor layer 200 to cross the active pattern, a dielectric layer, which is provided between the active pattern and the gate electrode, a gate spacer, which is provided to cover a side surface of the gate electrode, and source and drain electrodes, which are formed on opposites end portions of the active pattern and are electrically disconnected from the gate electrode by the gate spacer. A portion of the active pattern, which is provided between the source and drain electrodes, may be used as a channel region of the core/peripheral transistor 210. The active pattern may include the same semiconductor material as the core/peripheral semiconductor layer 200. In some implementations, the active pattern may include a plurality of semiconductor patterns, which are sequentially stacked on the substrate, and the gate electrode may include metal patterns, which are provided between the semiconductor patterns to fill spaces between the semiconductor patterns.

The power delivery network pattern PDN may be electrically coupled to the core/peripheral transistor 210. For example, the inner penetration via PDV may be provided in the core/peripheral semiconductor layer 200. The inner penetration via PDV may vertically penetrate the core/peripheral semiconductor layer 200 and the active pattern of the core/peripheral transistor 210. The inner penetration via PDV may be vertically extended to be connected to the core/peripheral transistor 210. For example, in the active pattern of the core/peripheral transistor 210, the inner penetration via PDV may be directly coupled to the source or drain electrode of the core/peripheral transistor 210.

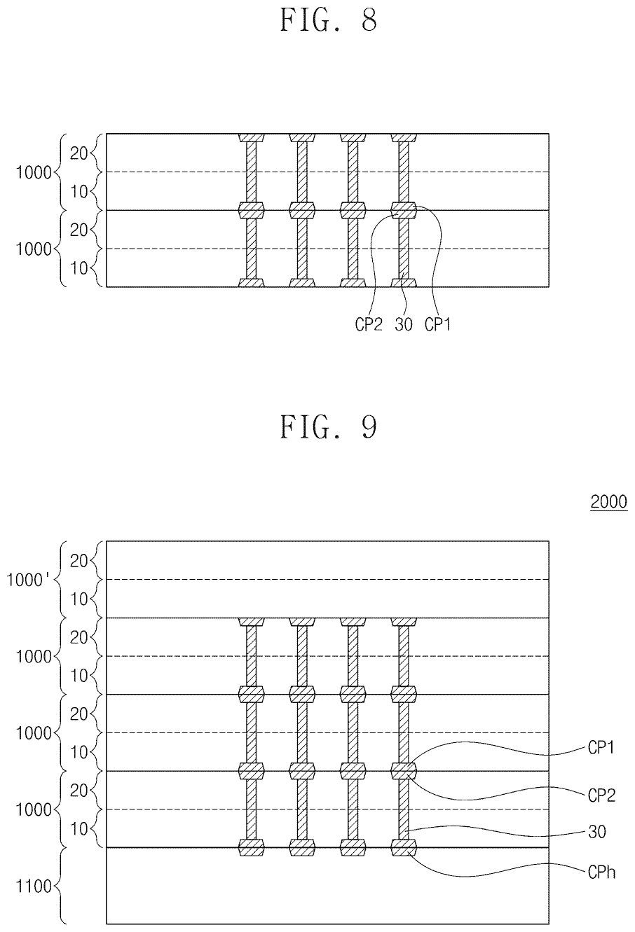

FIG. 8 is a sectional view illustrating an example of a plurality of semiconductor memory devices.

Referring to FIG. 8, a plurality of memory chips 1000 may be vertically stacked. The memory chips 1000 may have substantially the same or similar features as the memory chips described with reference to FIGS. 3A to 6A, 3B to 6B, and 7. Each of the memory chips 1000 may include the cell chip 10 and the core/peripheral chip 20, which are vertically stacked. Penetration vias 30 may be provided in each of the cell chip 10 and the core/peripheral chip 20. In some implementations, the cell chips 10 and the core/peripheral chips 20 may be alternately stacked. FIG. 8 illustrates an example, in which two memory chips 1000 are provided, but the concept is not limited to this example. For example, three or more memory chips 1000 may be stacked.

The memory chips 1000 may be electrically connected to each other through the penetration vias 30. The penetration vias 30 of the memory chips 1000 may include the penetration vias 30, which are provided in the cell chip 10, and the penetration vias 30, which are provided in the core/peripheral chip 20. In FIG. 8, the penetration vias 30 of the cell chip 10 are illustrated to be physically connected to the penetration vias 30 of the core/peripheral chip 20, but the concept is not limited to this example. For example, the penetration vias 30 of the cell chip 10 and the penetration vias 30 of the core/peripheral chip 20 may be connected to each other through additional conductive elements.

The penetration vias 30 in a pair of the memory chips 1000, which are vertically adjacent to each other, may be electrically connected to each other through a first contact pad CP1 and a second contact pad CP2. The first contact pad CP1 and the second contact pad CP2 may be in contact with each other. Each of the first and second contact pads CP1 and CP2 may be a conductive pad or a conductive bump.

FIG. 9 is a sectional view illustrating an example of a semiconductor package including a semiconductor memory device.

Referring to FIG. 9, a semiconductor package 2000 may include a base chip 1100 and a plurality of memory chips 1000 and 1000′ on the base chip 1100. The base chip 1100 may be electrically connected to the memory chips 1000 and 1000′ and may include a host core or a buffer die. The host core may include a processor, which is configured to execute various operations. The buffer die may be configured to receive commands, data, and signals, which are transmitted from the outside, and to send them to the memory chips 1000 and 1000′. In other words, the memory chips 1000 and 1000′, which are connected to the base chip 1100, may be used to execute various tasks, depending on signals transmitted from the base chip 1100.

The memory chips 1000 and 1000′ may be electrically connected to the base chip 1100 through the penetration vias 30. In some implementations, the base chip 1100 may include a base contact pad CPh provided at the highest level thereof, and the penetration vias 30 may be connected to the base chip 1100 through the base contact pad CPh. In some implementations, the penetration vias 30 may not be provided in the uppermost memory chip 1000′, but the concept is not limited to this example.

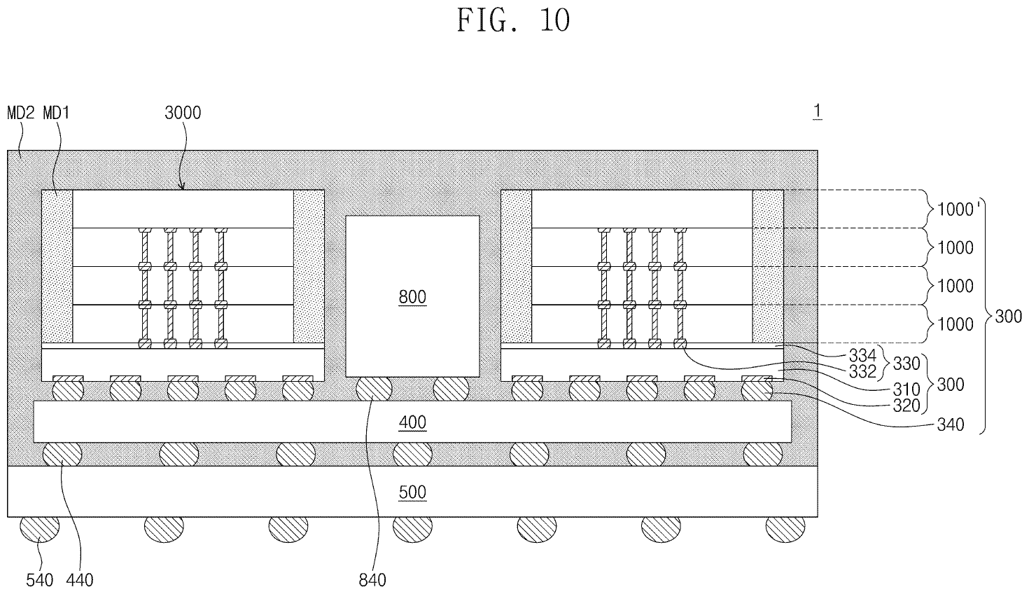

FIG. 10 is a sectional view illustrating an example of a semiconductor package including a semiconductor memory device.

Referring to FIG. 10, a semiconductor package 1 may include package substrates 400 and 500, a memory structure 3000, and a host structure 800. The memory structure 3000 and the host structure 800 may be provided on the package substrates 400 and 500 and may be horizontally spaced apart from each other. The memory structure 3000 and the host structure 800 may be electrically connected to each other through the package substrates 400 and 500.

In some implementations, the package substrates 400 and 500 may include a first package substrate 400 and a second package substrate 500. The first package substrate 400 may be placed on the second package substrate 500, and the memory structure 3000 and the host structure 800 may be placed on the first package substrate 400. The first package substrate 400 may be an interposer, and the second package substrate 500 may be a printed circuit board (PCB). A first connection terminal 440 may electrically connect the first package substrate 400 to the second package substrate 500. A second connection terminal 540 may electrically connect the semiconductor package 1 to an external device (e.g., a mainboard).

The memory structure 3000 may include a base chip 300, the memory chips 1000 and 1000′ on the base chip 300, a first mold layer MD1 enclosing the memory chips 1000 and 1000′, and a memory connection terminal 340 between the base chip 300 and the package substrates 400 and 500. The base chip 300 may correspond to the base chip 1100 of FIG. 9.

The base chip 300 may include a base layer 310, an upper interconnection layer 330 provided on a surface (e.g., a top surface) of the base layer 310, and a lower base pad 320 exposed through an opposite surface (e.g., a bottom surface) of the base layer 310. The upper interconnection layer 330 may include an upper base pad 332 and a base protection layer 334 enclosing the upper base pad 332.

The base chip 300 may be configured to realize the redistribution of the memory chips 1000 and 1000′. The upper base pad 332 and the lower base pad 320 may be electrically connected to circuit interconnection lines in the base layer 310 and may constitute a redistribution circuit in conjunction with the circuit interconnection lines. The memory connection terminal 340 may be placed between the lower base pad 320 and the first package substrate 400. The memory connection terminal 340 may include a solder ball or a solder bump. The first mold layer MD1 may include an insulating material. As an example, the first mold layer MD1 may include an epoxy molding compound (EMC).

The host structure 800 may be a data processing device. A host connection terminal 840 may be interposed between the host structure 800 and the first package substrate 400. The host connection terminal 840 may connect the host structure 800 electrically to the first package substrate 400. A second mold layer MD2 may be disposed on the first package substrate 400 to enclose the memory structure 3000 and the host structure 800.

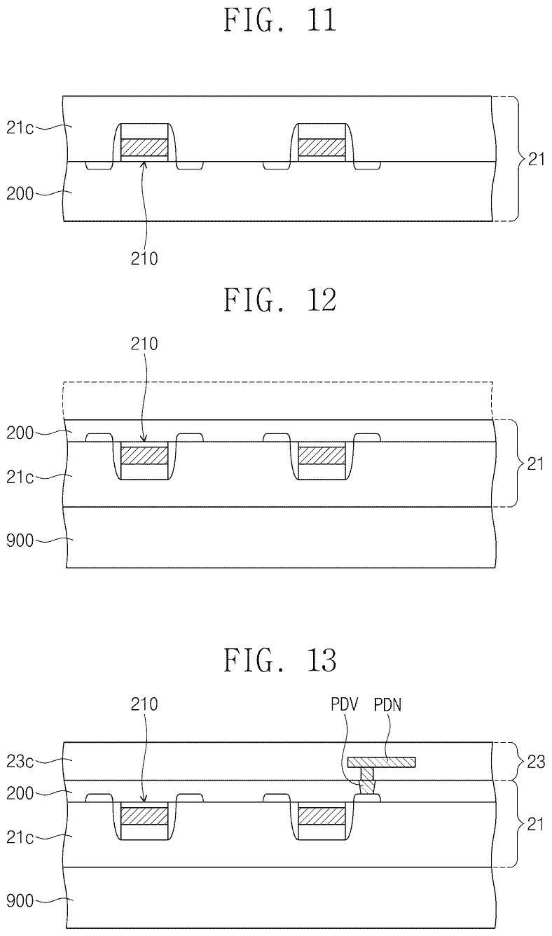

FIGS. 11 to 16 are sectional views illustrating an example of a method of fabricating a semiconductor memory device.

Referring to FIG. 11, the core/peripheral semiconductor layer 200 may be provided. The core/peripheral semiconductor layer 200 may be a semiconductor substrate (e.g., a single crystalline silicon substrate, a silicon-germanium substrate, a silicon-on-insulator (SOI) substrate) that is formed of or includes a semiconductor material.

The core/peripheral transistor 210 may be formed on the core/peripheral semiconductor layer 200. For example, a dielectric layer and a conductive layer may be formed on the core/peripheral semiconductor layer 200, the dielectric layer and the conductive layer may be patterned to form a gate insulating layer and a gate electrode, gate spacers may be formed on side surfaces of the gate electrode, and source and drain regions may be formed by injecting impurities into upper portions of the core/peripheral semiconductor layer 200 using the gate spacer as an ion mask. However, the concept is not limited to this example, and the method of forming the core/peripheral transistor 210 may be variously changed. Furthermore, the core/peripheral transistor 210 may not be limited to the planar-type transistor described above.

The second interlayer insulating layer 21c may be formed by coating or depositing an insulating material on the front surface of the core/peripheral semiconductor layer 200. The second interlayer insulating layer 21c may cover the core/peripheral transistor 210. The core/peripheral semiconductor layer 200, the core/peripheral transistor 210, and the second interlayer insulating layer 21c may constitute the driving layer 21.

Referring to FIG. 12, the structure of FIG. 11 may be inverted. Thus, the core/peripheral semiconductor layer 200 may be placed on the second interlayer insulating layer 21c.

A first carrier substrate 900 may be attached to a surface of the second interlayer insulating layer 21c. The first carrier substrate 900 may be an insulating substrate containing glass or polymeric materials or a conductive substrate containing a metallic material. The first carrier substrate 900 may be attached to the second interlayer insulating layer 21c through an adhesive member provided on a top surface thereof. In some implementations, the adhesive member may include an adhesive tape.

Next, a first thinning process may be performed on the rear surface of the core/peripheral semiconductor layer 200. The rear surface of the core/peripheral semiconductor layer 200 may be polished by the first thinning process. For example, a planarization process (e.g., a chemical-mechanical polishing (CMP) process) may be performed on the rear surface of the core/peripheral semiconductor layer 200. A thickness of the core/peripheral semiconductor layer 200 may be reduced by the first thinning process. The core/peripheral semiconductor layer 200 may have a flat surface.

Referring to FIG. 13, the inner penetration via PDV may be formed in the core/peripheral semiconductor layer 200. For example, the core/peripheral semiconductor layer 200 may be etched to form a hole exposing the source electrode of the core/peripheral transistor 210, and then, the inner penetration via PDV may be formed by filling the hole with a conductive material.

The back-side interconnection layer 23 may be formed on the rear surface of the core/peripheral semiconductor layer 200. For example, the formation of the back-side interconnection layer 23 may include forming an insulating layer on the rear surface of the core/peripheral semiconductor layer 200, patterning the insulating layer to expose the inner penetration via PDV, forming a conductive layer on the insulating layer, patterning the conductive layer to form the power delivery network pattern PDN, and depositing an insulating material on the insulating layer to form the fourth interlayer insulating layer 23c. In the case where the power delivery network pattern PDN includes a plurality of interconnection layers, the formation of the power delivery network pattern PDN may include repeating the steps of depositing and patterning the insulating layer and depositing and patterning the conductive layer.

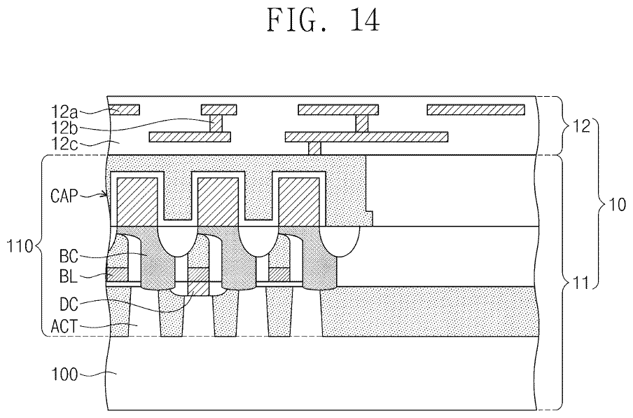

Referring to FIG. 14, the cell chip 10 may be formed. The cell chip 10 may include the data storing layer 11 and the cell interconnection layer 12.

In some implementations, the data storing layer 11 may be formed by performing, for example, a conventional process. The data storing layer 11 may include the cell semiconductor layer 100 and the memory cell layer 110. The memory cell layer 110 may include a BCAT-type DRAM device, which includes the active region ACT, the bit line node contact DC, the bit line BL, the storage node contact BC, and the capacitor CAP.

The cell interconnection layer 12 may be formed on the data storing layer 11. For example, the cell circuit interconnection lines 12a, the cell contact plugs 12b, and the first interlayer insulating layer 12c may be formed by repeating steps of depositing an insulating layer on a top surface of the data storing layer 11, patterning the insulating layer, depositing a conductive layer, and patterning the conductive layer, and here, the cell contact plugs 12b may be formed to electrically connect the memory cell layer 110 to the cell circuit interconnection lines 12a. However, the method of forming the cell interconnection layer 12 is not limited to the afore-described method, and in some implementations, the cell interconnection layer 12 may be formed by various methods.

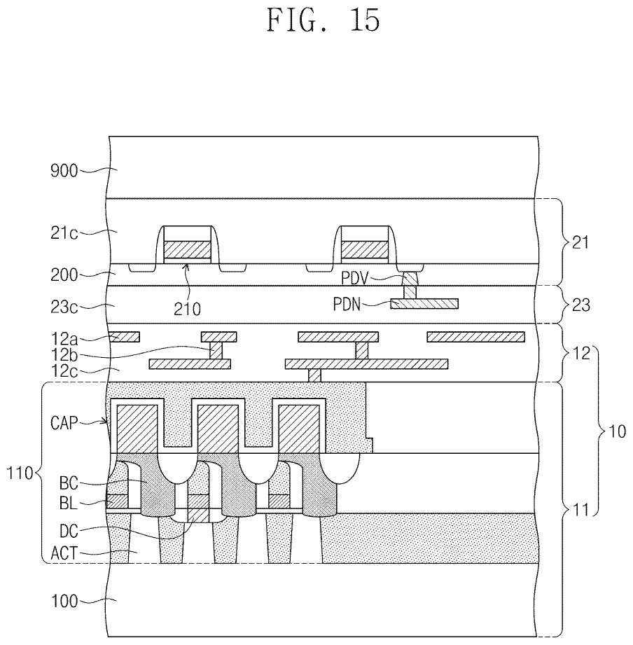

Referring to FIG. 15, the structure of FIG. 13 may be bonded to the cell chip 10. The first carrier substrate 900 may be aligned to the cell chip 10 such that the first interlayer insulating layer 12c faces the fourth interlayer insulating layer 23c. The first carrier substrate 900 may be disposed on the cell chip 10 such that the first interlayer insulating layer 12c is in contact with the fourth interlayer insulating layer 23c. A thermal treatment process may be performed on the first interlayer insulating layer 12c and the fourth interlayer insulating layer 23c. The first interlayer insulating layer 12c and the fourth interlayer insulating layer 23c may be bonded to each other by the thermal treatment process. For example, the first interlayer insulating layer 12c and the fourth interlayer insulating layer 23c may be bonded to form a single object. The bonding of the first interlayer insulating layer 12c and the fourth interlayer insulating layer 23c may be achieved in a natural manner. In detail, the first interlayer insulating layer 12c and the fourth interlayer insulating layer 23c may be formed of the same material (e.g., silicon oxide (SiO), silicon nitride (SiN), and silicon oxynitride (SiON)), and in this case, the first interlayer insulating layer 12c and the fourth interlayer insulating layer 23c may be bonded to each other by a hybrid bonding process of oxide, nitride, or oxynitride, which is caused by a surface activation phenomenon at an interface between the first interlayer insulating layer 12c and the fourth interlayer insulating layer 23c, which are in contact with each other.

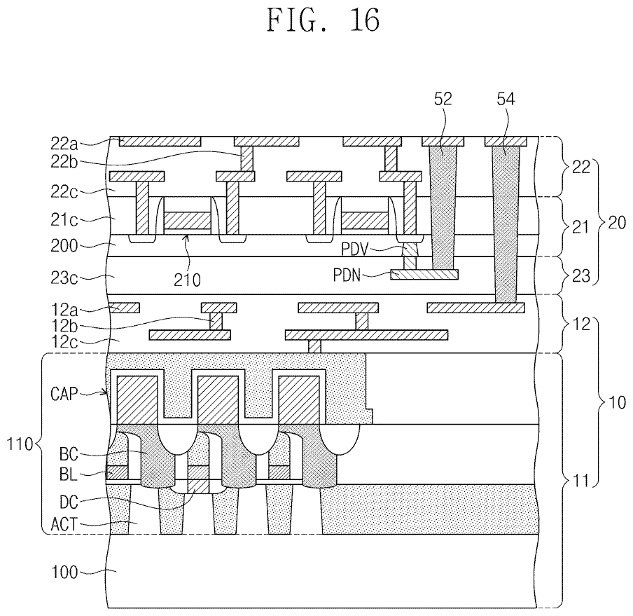

Referring to FIG. 16, the first carrier substrate 900 may be removed. Thus, a top surface of the driving layer 21 may be exposed to the outside.

A second thinning process may be performed on the top surface of the driving layer 21. In some implementations, the second thinning process may be performed to polish the top surface of the driving layer 21. For example, a planarization process (e.g., a chemical-mechanical polishing (CMP) process) may be performed on the top surface of the driving layer 21. A thickness of the second interlayer insulating layer 21c may be reduced by the second thinning process. The second thinning process may be performed to expose the top surface of the core/peripheral transistor 210. However, the concept is not limited to this example.

The core/peripheral interconnection layer 22 may be formed on the driving layer 21. For example, the core/peripheral interconnection layer 22 may include the core/peripheral circuit interconnection lines 22a, the core/peripheral contact plugs 22b, and the third interlayer insulating layer 22c, which are formed by repeating steps of depositing an insulating layer on the top surface of the driving layer 21, patterning the insulating layer, depositing a conductive layer, and patterning the conductive layer, and here, the core/peripheral contact plugs 22b may be formed to electrically connect the core/peripheral transistor 210 to the core/peripheral circuit interconnection lines 22a. However, the method of forming the core/peripheral interconnection layer 22 is not limited to the afore-described method, and in some implementations, the core/peripheral interconnection layer 22 may be formed by various methods.

In some implementations, the first and second outer penetration vias 52 and 54 may be formed during the process of forming the core/peripheral interconnection layer 22. For example, a first penetration hole may be formed by patterning the third interlayer insulating layer 22c, the second interlayer insulating layer 21c, the core/peripheral semiconductor layer 200, and the fourth interlayer insulating layer 23c, and a second penetration hole may be formed by patterning the third interlayer insulating layer 22c, the second interlayer insulating layer 21c, the core/peripheral semiconductor layer 200, the fourth interlayer insulating layer 23c, and the first interlayer insulating layer 12c. The first penetration hole may be formed to have a bottom surface exposing the power delivery network pattern PDN. The second penetration hole may be formed to have a bottom surface exposing the cell circuit interconnection line 12a. The first and second outer penetration vias 52 and 54 may be formed through a process of filling the first penetration hole and the second penetration hole with a conductive material.

Referring back to FIG. 3A, the first passivation layer 60 may be formed by depositing an insulating material on the core/peripheral interconnection layer 22. Thereafter, the first passivation layer 60 may be patterned to expose the core/peripheral circuit interconnection lines 22a, and then, the chip pads 62 may be formed by depositing and patterning a conductive layer on the first passivation layer 60.

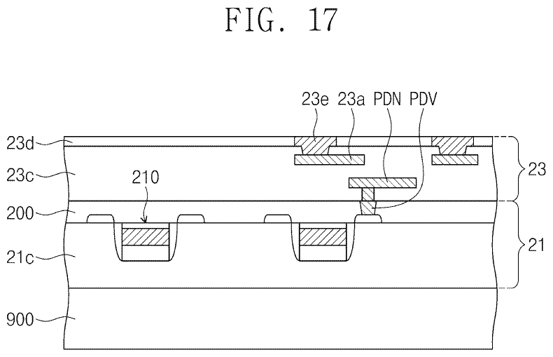

FIGS. 17 to 20 are sectional views illustrating a method of fabricating a semiconductor memory device in some implementations.

Referring to FIG. 17, the back-side interconnection lines 23a may be further formed on the structure of FIG. 13, in particular, on the back-side interconnection layer 23. For example, the back-side interconnection lines 23a and the fourth interlayer insulating layer 23c may be formed by repeating steps of depositing an insulating layer on a top surface of the fourth interlayer insulating layer 23c, patterning the insulating layer, depositing a conductive layer, and patterning the conductive layer. However, the method of forming the back-side interconnection layer 23 is not limited to the afore-described method, and in some implementations, the back-side interconnection layer 23 may be formed by various methods.

The third passivation layer 23d may be formed by depositing an insulating material on the fourth interlayer insulating layer 23c. Next, the third passivation layer 23d may be patterned to expose the back-side interconnection lines 23a, and then, the second inner pads 23e may be formed by depositing and patterning a conductive layer on the third passivation layer 23d.

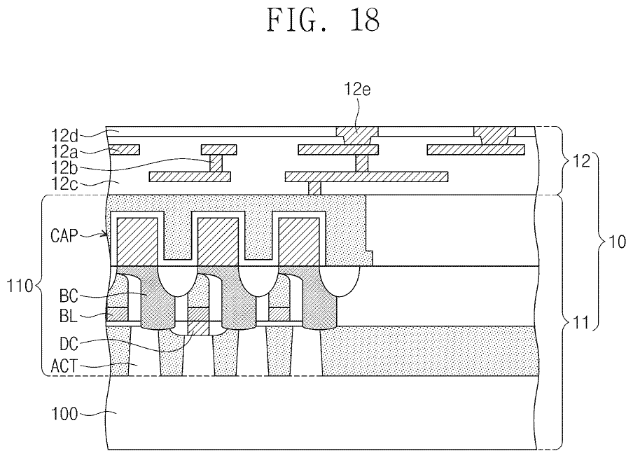

Referring to FIG. 18, the second passivation layer 12d may be formed on depositing an insulating material on the first interlayer insulating layer 12c in the structure of FIG. 14. Thereafter, the second passivation layer 12d may be patterned to expose the cell circuit interconnection lines 12a, and then, the first inner pads 12e may be formed by depositing and patterning a conductive layer on the second passivation layer 12d.

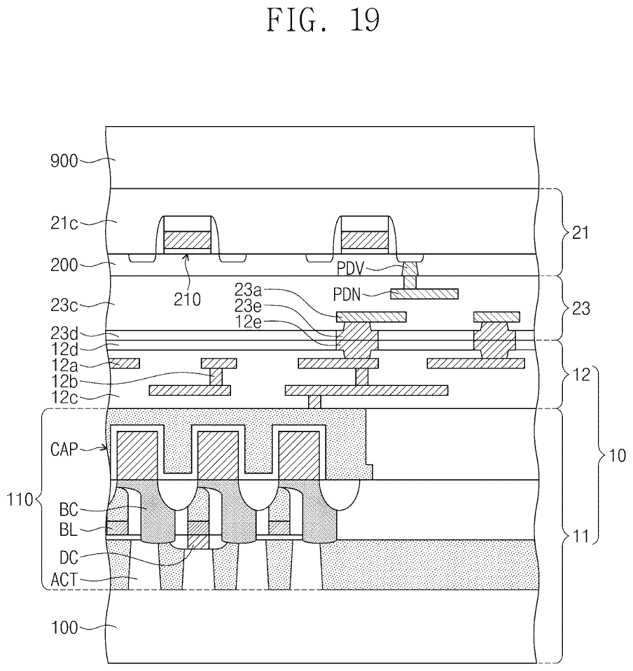

Referring to FIG. 19, the structure of FIG. 17 may be bonded to the cell chip 10. The first carrier substrate 900 may be aligned to the cell chip 10 such that the second inner pads 23e are placed over the first inner pads 12e of the cell chip 10. The first carrier substrate 900 may be disposed on the cell chip 10 such that the second inner pads 23e are in contact with the first inner pads 12e. A thermal treatment process may be performed on the first inner pads 12e and the second inner pads 23e. The first inner pads 12e and the second inner pads 23e may be bonded to each other by the thermal treatment process. For example, the first inner pads 12e and the second inner pads 23e may be bonded to form a single object. The bonding of the first inner pads 12e and the second inner pads 23e may be achieved in a natural manner. In detail, the first inner pads 12e and the second inner pads 23e may be formed of the same material (e.g., copper (Cu)), and in this case, the first inner pads 12e and the second inner pads 23e may be bonded to each other by an intermetal hybrid bonding process caused by a surface activation phenomenon at an interface between the first inner pads 12e and the second inner pads 23e, which are in contact with each other.

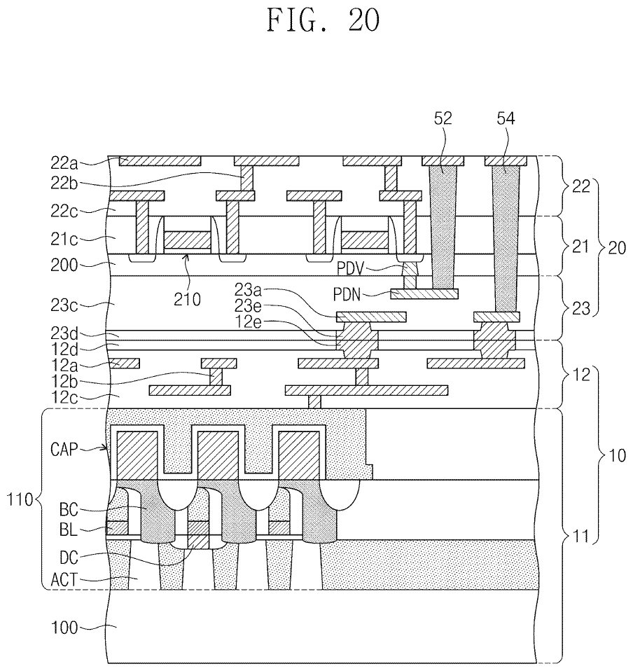

Referring to FIG. 20, the process described with reference to FIG. 16 may be performed to remove the first carrier substrate 900, a second thinning process may be performed on the top surface of the driving layer 21, the core/peripheral interconnection layer 22 may be formed on the driving layer 21, and then the first and second outer penetration vias 52 and 54 may be formed.

Referring to FIG. 4A, the first passivation layer 60 may be formed by depositing an insulating material on the core/peripheral interconnection layer 22. Thereafter, the first passivation layer 60 may be patterned to expose the core/peripheral circuit interconnection lines 22a, and then, the chip pads 62 may be formed by depositing and patterning a conductive layer on the first passivation layer 60.

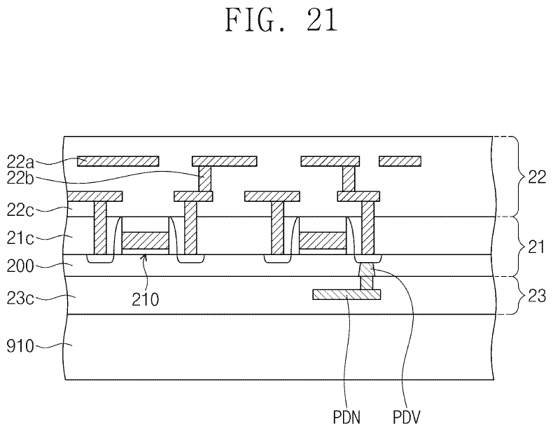

FIGS. 21 to 23 are sectional views illustrating a method of fabricating a semiconductor memory device in some implementations.

Referring to FIG. 21, a second carrier substrate 910 may be attached to the structure of FIG. 13, in particular, to the back-side interconnection layer 23. The second carrier substrate 910 may be an insulating substrate containing glass or polymeric materials or a conductive substrate containing a metallic material. The second carrier substrate 910 may be attached to the fourth interlayer insulating layer 23c through an adhesive member provided on a surface thereof. In some implementations, the adhesive member may include an adhesive tape.

The first carrier substrate 900 may be removed. Thus, the top surface of the driving layer 21 may be exposed to the outside.

The core/peripheral interconnection layer 22 may be formed on the driving layer 21. For example, the core/peripheral interconnection layer 22 may include the core/peripheral circuit interconnection lines 22a, the core/peripheral contact plugs 22b, and the third interlayer insulating layer 22c, which are formed by repeating steps of depositing an insulating layer on the top surface of the driving layer 21, patterning the insulating layer, depositing a conductive layer, and patterning the conductive layer, and here, the core/peripheral contact plugs 22b may be formed to electrically connect the core/peripheral transistor 210 to the core/peripheral circuit interconnection lines 22a. However, the method of forming the core/peripheral interconnection layer 22 is not limited to the afore-described method, and in some implementations, the core/peripheral interconnection layer 22 may be formed by various methods.

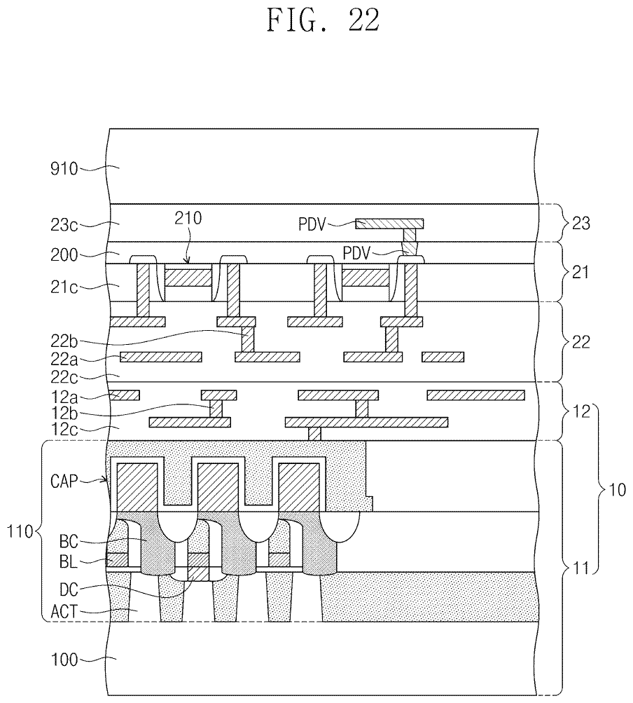

Referring to FIG. 22, the structure of FIG. 21 may be bonded to the structure of FIG. 14, in particular, to the cell chip 10. The second carrier substrate 910 may be aligned to the cell chip 10 such that the first interlayer insulating layer 12c and the third interlayer insulating layer 22c face each other. The second carrier substrate 910 may be disposed on the cell chip 10 such that the third interlayer insulating layer 22c is in contact with the first interlayer insulating layer 12c. A thermal treatment process may be performed on the first interlayer insulating layer 12c and the third interlayer insulating layer 22c. The first interlayer insulating layer 12c and the third interlayer insulating layer 22c may be bonded to each other by the thermal treatment process. For example, the first interlayer insulating layer 12c and the third interlayer insulating layer 22c may be bonded to form a single object. The bonding of the first interlayer insulating layer 12c and the third interlayer insulating layer 22c may be achieved in a natural manner. In detail, the first interlayer insulating layer 12c and the third interlayer insulating layer 22c may be formed of the same material (e.g., silicon oxide (SiO), silicon nitride (SiN), and silicon oxynitride (SiON)), and in this case, the first interlayer insulating layer 12c and the third interlayer insulating layer 22c may be bonded to each other by a hybrid bonding process of oxide, nitride, or oxynitride, which is caused by a surface activation phenomenon at an interface between the first interlayer insulating layer 12c and the third interlayer insulating layer 22c, which are in contact with each other.

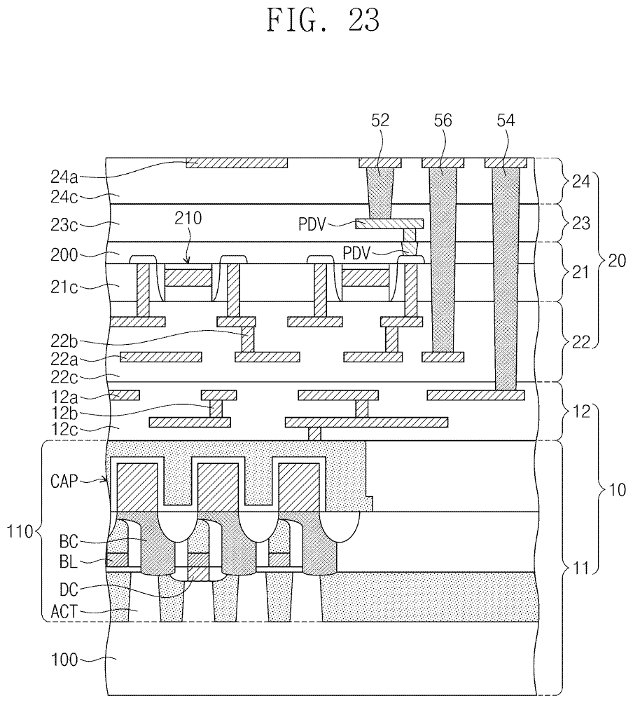

Referring to FIG. 23, the second carrier substrate 910 may be removed. Thus, the top surface of the back-side interconnection layer 23 may be exposed to the outside.

The additional interconnection layer 24 may be formed on the back-side interconnection layer 23. For example, the additional interconnection lines 24a and the fifth interlayer insulating layer 24c may be formed by repeating steps of depositing an insulating layer on the top surface of the back-side interconnection layer 23, patterning the insulating layer, depositing a conductive layer, and patterning the conductive layer. However, the method of forming the additional interconnection layer 24 is not limited to the afore-described method, and in some implementations, the additional interconnection layer 24 may be formed by various methods.

In some implementations, the first outer penetration via 52, the second outer penetration via 54, and the third outer penetration via 56 may be formed during the process of forming the additional interconnection layer 24. For example, a first penetration hole may be formed by patterning the fifth interlayer insulating layer 24c and the fourth interlayer insulating layer 23c, and a second penetration hole may be formed by patterning the fifth interlayer insulating layer 24c, the fourth interlayer insulating layer 23c, the core/peripheral semiconductor layer 200, the second interlayer insulating layer 21c, the third interlayer insulating layer 22c, and the first interlayer insulating layer 12c, and a third penetration hole may be formed by patterning the fifth interlayer insulating layer 24c, the fourth interlayer insulating layer 23c, the core/peripheral semiconductor layer 200, the second interlayer insulating layer 21c, and the third interlayer insulating layer 22c. The first penetration hole may be formed to have a bottom surface exposing the power delivery network pattern PDN. The second penetration hole may be formed to have a bottom surface exposing the cell circuit interconnection line 12a. The third penetration hole may be formed to have a bottom surface exposing the core/peripheral circuit interconnection line 22a. The first outer penetration via 52, the second outer penetration via 54, and the third outer penetration via 56 may be formed by filling the first penetration hole, the second penetration hole, and the third penetration hole with a conductive material.

Referring to FIG. 5A, the first passivation layer 60 may be formed by depositing an insulating material on the additional interconnection layer 24. Thereafter, the first passivation layer 60 may be patterned to expose the additional interconnection lines 24a, and the chip pads 62 may be formed by depositing and patterning a conductive layer on the first passivation layer 60.

In a semiconductor memory device in some implementations, a core/peripheral interconnection layer, which is used to deliver an operation signal in a core/peripheral chip, may be provided on a front surface of a core/peripheral semiconductor layer, and a back-side interconnection layer, which is used to deliver a power signal, may be provided on a rear surface of the core/peripheral semiconductor layer. That is, interconnection lines, which are used to drive the core/peripheral chip, may be disposed on the front and rear surfaces of the core/peripheral semiconductor layer in a vertically-separated manner. Thus, it may be possible to reduce a planar area for the interconnection line in the core/peripheral chip and thereby to reduce a size of the semiconductor memory device. In addition, an interconnection density may be lowered in each of the core/peripheral interconnection layer and the back-side interconnection layer, and this may prevent technical issues (e.g., parasitic capacitance or short circuit), which may occur when the interconnection density is high. That is, in some implementations, it may be possible to improve the electrical characteristics of the semiconductor memory device.

Furthermore, since an interlayer insulating layer of a cell chip is directly bonded to an interlayer insulating layer of the core/peripheral chip through a hybrid bonding structure, the cell chip and the core/peripheral chip may be robustly bonded to each other. That is, it may be possible to improve the structural stability of the semiconductor memory device.

In addition, a length of an electric connection path from a power delivery network pattern to a core/peripheral transistor may be reduced, and a length of an electric connection path from chip pads to the power delivery network pattern may be reduced. In this case, it may be possible to improve the electrical characteristics of the semiconductor memory device.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations of the concept have been shown and described, it will be understood by one of ordinary skill in the art that variations in form and detail may be made therein without departing from the spirit and scope of the attached claims.

What is claimed is:

1. A semiconductor memory device, comprising:
a first substrate having a cell array region;
a first interlayer insulating layer covering the first substrate;
a second substrate disposed on the first interlayer insulating layer, the second substrate having a core region;
a second interlayer insulating layer covering an active surface of the second substrate;
a third interlayer insulating layer covering an inactive surface of the second substrate;
a power delivery network pattern disposed in the third interlayer insulating layer;
an inner penetration via extending through the second substrate, the inner penetration via connecting a plurality of transistors with the power delivery network pattern, the plurality of transistors being positioned on the active surface of the second substrate;
a first outer penetration via extending through at least one of the second interlayer insulating layer, the second substrate, or the third interlayer insulating layer, the first outer penetration via being coupled to the power delivery network pattern; and
a second outer penetration via extending through the second interlayer insulating layer, the second substrate, and the third interlayer insulating layer, the second outer penetration via being electrically connected with the cell array region.

2. The semiconductor memory device of claim 1, wherein the inactive surface of the second substrate faces the first interlayer insulating layer, and
wherein the first interlayer insulating layer contacts the third interlayer insulating layer.

3. The semiconductor memory device of claim 2, wherein the first outer penetration via extends through the second interlayer insulating layer, the second substrate, and the third interlayer insulating layer, and the first outer penetration via is coupled to the power delivery network pattern.

4. The semiconductor memory device of claim 2, wherein the first interlayer insulating layer and the third interlayer insulating layer are formed with the same material, and the first interlayer insulating layer and the third interlayer insulating layer form a single object.

5. The semiconductor memory device of claim 1, comprising:
a first pad on the first interlayer insulating layer, the first pad being electrically connected with the cell array region; and
a second pad on the third interlayer insulating layer, the second pad being electrically connected with the second outer penetration via,
wherein the inactive surface of the second substrate faces the first interlayer insulating layer, and
wherein the first pad and the second pad contact each other.

6. The semiconductor memory device of claim 5, comprising:
a first passivation layer on the first interlayer insulating layer, the first passivation layer enclosing the first pad; and
a second passivation layer on the third interlayer insulating layer, the second passivation layer enclosing the second pad,
wherein the first passivation layer and the second passivation layer contact each other.

7. The semiconductor memory device of claim 5, wherein the first pad includes a same material as the second pad, and
wherein the first pad and the second pad define a single object.

8. The semiconductor memory device of claim 1, comprising a first interconnection pattern in the third interlayer insulating layer,
wherein the active surface of the second substrate faces the first interlayer insulating layer, and
wherein the first interlayer insulating layer contacts the second interlayer insulating layer.

9. The semiconductor memory device of claim 8, comprising a third outer penetration via extending through the second interlayer insulating layer, the second substrate, and the third interlayer insulating layer, wherein the third outer penetration via is electrically connected with the cell array region,
wherein the first outer penetration via extends through the third interlayer insulating layer and connects the power delivery network pattern with the first interconnection pattern, and
wherein the third outer penetration via connects a second interconnection pattern in the second interlayer insulating layer with the first interconnection pattern in the second interlayer insulating layer.

10. The semiconductor memory device of claim 8, wherein the first interlayer insulating layer includes a same material as the second interlayer insulating layer, and
wherein the first interlayer insulating layer and the second interlayer insulating layer define a single object.

11. The semiconductor memory device of claim 1, comprising:
a plurality of word lines in the cell array region, the plurality of word lines being parallel to each other; and
a plurality of bit lines in the cell array region, the plurality of bit lines crossing the plurality of word lines, the plurality of bit lines being parallel to each other,
wherein the plurality of word lines are buried in the first substrate, and
wherein the plurality of bit lines are disposed on the first substrate.

12. The semiconductor memory device of claim 1, wherein the second substrate comprises a peripheral circuit region electrically connected with the core region.

13. The semiconductor memory device of claim 1, wherein the power delivery network pattern comprises a head portion and a via portion, which is extended from a top surface of the head portion toward the second substrate.

14. A semiconductor memory device, comprising:
a first substrate having a cell array region;
a first interlayer insulating layer covering the first substrate;
a plurality of first interconnection lines disposed in the first interlayer insulating layer, the plurality of first interconnection lines being electrically connected with the cell array region;
a second substrate disposed on the first interlayer insulating layer, the second substrate having a logic region electrically connected with the cell array region;
a transistor provided in the logic region, the transistor on a first surface of the second substrate;
a second interlayer insulating layer covering the first surface of the second substrate;
a plurality of second interconnection lines provided in the second interlayer insulating layer, the plurality of second interconnection lines being electrically connected with the transistor;
a third interlayer insulating layer covering a second surface, which is opposite to the first surface of the second substrate;
a power delivery network pattern provided in the third interlayer insulating layer;
a first outer penetration via extending through at least one of the second interlayer insulating layer, the second substrate, and the third interlayer insulating layer, the first outer penetration via being connected to the power delivery network pattern; and
a second outer penetration via extending through the second interlayer insulating layer, the second substrate, and the third interlayer insulating layer, the second outer penetration via being connected with the plurality of first interconnection lines,
wherein the power delivery network pattern comprises a first head portion and a first via portion, which is extended from a top surface of the first head portion toward the second substrate, and
wherein the plurality of first interconnection lines comprise a second head portion and a second via portion, which is extended from a bottom surface of the second head portion toward the first substrate.

15. The semiconductor memory device of claim 14, comprising an inner penetration via extending through the second substrate, wherein the inner penetration via connects the transistor with the power delivery network pattern.

16. The semiconductor memory device of claim 14, wherein the first interlayer insulating layer contacts the third interlayer insulating layer,
wherein the first interlayer insulating layer includes a same material as the third interlayer insulating layer, and the first interlayer insulating layer and the third interlayer insulating layer define a single object, and
wherein the first outer penetration via extends through the second interlayer insulating layer, the second substrate, and the third interlayer insulating layer, and the first outer penetration via is coupled to the power delivery network pattern.

17. The semiconductor memory device of claim 14, comprising:
a third interconnection line provided in the third interlayer insulating layer, the third interconnection line being electrically connected with the power delivery network pattern through the first outer penetration via; and
a third outer penetration via extending through the second interlayer insulating layer, the second substrate, and the third interlayer insulating layer, the third outer penetration via electrically connecting the plurality of first interconnection lines with the plurality of second interconnection lines,
wherein the first interlayer insulating layer contacts the second interlayer insulating layer, and
wherein the first interlayer insulating layer includes a same material as the second interlayer insulating layer, and the first interlayer insulating layer and the second interlayer insulating layer define a single object.

18. The semiconductor memory device of claim 14, comprising:
a first pad provided on the first interlayer insulating layer, the first pad being electrically connected with the cell array region;
a first passivation layer provided on the first interlayer insulating layer, the first passivation layer enclosing the first pad;
a second pad provided on the third interlayer insulating layer, the second pad being electrically connected with the second outer penetration via; and
a second passivation layer provided on the third interlayer insulating layer, the second passivation layer enclosing the second pad,
wherein the first pad and the second pad contact each other, the first pad includes a same material as the second pad, and the first pad and the second pad define a single object.

19. The semiconductor memory device of claim 14, comprising:
a plurality of word lines in the cell array region, the plurality of word lines being parallel to each other; and
a plurality of bit lines in the cell array region, the plurality of bit lines crossing the plurality of word lines, the plurality of bit lines being parallel to each other,
wherein the plurality of word lines are buried in the first substrate, and
wherein the plurality of bit lines are disposed on the first substrate.

20. A semiconductor memory device, comprising:
a cell chip;
a core/peripheral chip on the cell chip; and
a pad on the core/peripheral chip,
wherein the cell chip comprises:
a first substrate;
a plurality of word lines buried in the first substrate, the plurality of word lines being parallel to each other;
a plurality of bit lines disposed on the first substrate, the plurality of bit lines crossing the plurality of word lines, the plurality of bit lines being parallel to each other;
a first interlayer insulating layer provided on the first substrate, the first interlayer insulating layer covering the plurality of word lines and the plurality of bit lines; and
a plurality of first interconnection lines provided in the first interlayer insulating layer,
wherein the core/peripheral chip comprises:
a second substrate;
a plurality of transistors provided on an active surface of the second substrate;
a second interlayer insulating layer provided on the active surface of the second substrate, the second interlayer insulating layer covering the plurality of transistors;
a plurality of second interconnection lines provided in the second interlayer insulating layer;
a contact provided in the second interlayer insulating layer, the contact connecting the plurality of second interconnection lines with the plurality of transistors;
a third interlayer insulating layer provided on an inactive surface of the second substrate;
a power delivery network pattern provided in the third interlayer insulating layer;
an inner penetration via extending through the second substrate, the inner penetration via connecting the plurality of transistors with the power delivery network pattern; and
a plurality of third interconnection lines provided in the third interlayer insulating layer,
wherein the first interlayer insulating layer and the second interlayer insulating layer contact each other,
wherein the pad extends through the third interlayer insulating layer and is coupled to the plurality of third interconnection lines, and
wherein the power delivery network pattern and the plurality of third interconnection lines are connected with each other through a penetration via, the penetration via extending through the third interlayer insulating layer.
